(19) United States
(12) Patent Application Publication
(10) Pub. No.: US 2026/0068564 A1
(43) Pub. Date: Mar. 5, 2026

(54) CYCLIC PROCESSING METHODS FOR DEFECT REDUCTION, AND RELATED APPARATUS, DEVICES, AND PROCESSING CHAMBERS

(71) Applicant: Applied Materials, Inc., Santa Clara, CA (US)

(72) Inventors: Xuebin LI, Sunnyvale, CA (US); Himani ARORA, Albany, CA (US); He REN, San Jose, CA (US); Tianchen YANG, Santa Clara, CA (US); Raman GAIRE, Mechanicville, NY (US); Xiangyu LIU, Sunnyvale, CA (US); John TOLLE, Gilbert, AZ (US); Joe MARGETIS, Gilbert, AZ (US); Abhishek DUBE, Fremont, CA (US); Saurabh CHOPRA, Santa Clara, CA (US)

(21) Appl. No.: 19/313,318

(22) Filed: Aug. 28, 2025

Related U.S. Application Data
(60) Provisional application No. 63/690,266, filed on Sep. 3, 2024.
(60) Provisional application No. 63/759,397, filed on Feb. 17, 2025.
(60) Provisional application No. 63/762,351, filed on Feb. 24, 2025.
(60) Provisional application No. 63/824,690, filed on Jun. 16, 2025.

(51) Int. Cl. H01L 21/3065; H01L 21/02; H10D 30/01; H10D 62/00

(52) U.S. Cl. CPC H01L 21/3065; H10D 62/021; H10D 30/019

(57) ABSTRACT

Systems and methods for manufacturing semiconductor devices, specifically focusing on cyclic epitaxial growth and etching within a semiconductor structure are provided. The method includes forming a source and drain material on a structure of a substrate and etching the source and drain material. The etching is conducted in a plurality of etch cycles that respectively include flowing a purge gas and flowing an etch gas to etch the source and drain material. The source and drain material can be an n-type doped silicon-containing layer formed using a dopant source including an organophosphine. This cycle is repeated to achieve the targeted thickness. The process enhances the quality and performance of multi-gate devices like gate-all-around transistors by reducing defects and improving uniformity.

### CROSS REFERENCE TO RELATED APPLICATIONS

This application claims the benefit of U.S. Provisional Patent Application Ser. No. 63/690,266, filed Sep. 3, 2024, U.S. Provisional Patent Application Ser. No. 63/759,397, filed Feb. 17, 2025, U.S. Provisional Patent Application Ser. No. 63/762,351, filed Feb. 24, 2025, U.S. Provisional Patent Application Ser. No. 63/824,690, filed Jun. 16, 2025, all of which are incorporated by reference herein in their entirety.

### TECHNICAL FIELD

The present disclosure generally relates to semiconductor devices and methods for manufacturing semiconductor devices. More particularly, the disclosure relates to systems and methods of bottom-up epitaxial growth within a semiconductor structure.

### BACKGROUND

The electronics industry is experiencing an ever-increasing demand for smaller and faster electronic devices, which are simultaneously able to support a greater number of increasingly complex and sophisticated functions. Accordingly, there is a continuing trend in the semiconductor industry to manufacture low-cost, high-performance, and low-power integrated circuits (ICs). These goals have been achieved in large part by scaling down semiconductor IC dimensions (e.g., minimum feature size) and thus improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reducing OFF-state current, and reducing short-channel effects (SCEs). One such multi-gate device is the gate-all-around transistor (GAA). In a GAA device, all side surfaces of the channel region are surrounded by the gate electrode, which allows for fuller depletion in the channel region and results in less short-channel effects due to a steeper sub-threshold current swing and smaller drain induced barrier lowering (DIBL).

As transistor dimensions are scaled down to smaller technology nodes, there is a need for further improvements in GAA design and manufacturing.

### SUMMARY

The present disclosure generally relates to semiconductor devices and methods for manufacturing semiconductor devices. More particularly, the disclosure relates to systems and methods of bottom-up epitaxial growth within a semiconductor structure.

In one aspect, a method of substrate processing includes forming a source and drain material on a structure of a substrate and etching the source and drain material. The etching is conducted in a plurality of etch cycles that respectively include flowing a purge gas, and flowing an etch gas to etch the source and drain material.

Implementations of the aspects can include one or more of the following. The etch gas is flowed for an etch time and the purge gas is flowed for a purge time that is greater than the etch time. The etch time is 5.0 seconds or less, and the purge time is 5.0 seconds or less. A liner is formed on the structure, wherein the source and drain material is formed on the liner, the structure includes a plurality of stacks of the structure, the plurality of stacks respectively comprising a plurality of Si layers and a plurality of SiGe layers, and the liner lines the plurality of Si layers and spacers disposed outwardly of the plurality of SiGe layers. The etch gas includes one or more of: hydrochloric acid (HCl), chlorine gas (Cl₂), hydrogen bromide (HBr), phosphorus trichloride (PCl₃), arsenic trichloride (AsCl₃), or germanium trichloride (GeCl₄). A liner is formed on the structure using a formation temperature of 500 degrees Celsius or less, wherein the etch gas includes HCl and Cl₂ co-flowed in a carrier gas to enhance selectivity of the liner. The method further includes forming a liner on the structure using a formation temperature of 500 degrees Celsius or less and a second etching of the source and drain material after the plurality of etch cycles, the second etching including flowing a second etch gas, wherein the etch gas includes HCl and the second etch gas includes Cl₂. The forming and the etching are sequentially repeated for a plurality of cycles of a first dep-etch sequence, and then the forming and the second etching are sequentially repeated for a plurality of second cycles of a second dep-etch sequence. The forming of the source and drain material is conducted in a plurality of deposition cycles that respectively include a first deposition operation comprising simultaneously flowing a deposition gas and an etch composition at a first etch flow rate and a second deposition operation comprising simultaneously flowing the deposition gas and the etch composition at a second etch flow rate, wherein the second etch flow rate is larger than the first etch flow rate. The deposition gas flows at a deposition flow rate, the first etch flow rate and the second etch flow rate respectively are a ratio of the deposition flow rate, and the ratio is less than 0.20. The deposition gas includes a phosphorous dopant source gas including an organophosphine having the formula PRₙH₃₋ₙ, n is from 1 to 3, and R is an ethyl group, a propyl group, or a butyl group.

In another aspect, a method of substrate processing includes forming a source and drain material on a structure of a substrate. The forming of the source and drain material is conducted in a plurality of deposition cycles that respectively includes a first deposition operation and a second deposition operation. The first deposition operation includes simultaneously flowing a deposition gas and an etch composition at a first etch flow rate. The second deposition operation includes simultaneously flowing the deposition gas and the etch composition at a second etch flow rate. The second etch flow rate is larger than the first etch flow rate.

Implementations of the aspects can include one or more of the following. The deposition gas flows at a deposition flow rate, the first etch flow rate and the second etch flow rate respectively are a ratio of the deposition flow rate, and the ratio is less than 0.20. The deposition gas flows at a deposition flow rate, the first etch flow rate and the second etch flow rate respectively are a ratio of the deposition flow rate, and the ratio is 0.20 or higher. The second etch flow rate is a ratio of the first etch flow rate, and the ratio is greater than 1.0 and equal to or lesser than 1.4. The first etch flow rate is defined by a first etch-deposition ratio, and the second etch flow rate is defined by a second etch-deposition ratio that is greater than the first etch-deposition ratio. The first deposition operation has a first deposition time, and the second deposition operation has a second deposition time that is shorter than the first deposition time. The deposition gas includes a phosphorous dopant source gas including an organophosphine having the formula PRₙH₃₋ₙ, n is from 1 to 3, and R is an ethyl group, a propyl group, or a butyl group.

In yet another aspect, a non-transitory computer readable medium includes instructions that, when executed, cause a plurality of operations to be conducted. The plurality of operations includes forming a source and drain material on a structure of a substrate, and etching the source and drain material. The etching is conducted in a plurality of etch cycles that respectively include flowing a purge gas, and flowing an etch gas to etch the source and drain material.

Implementations of the aspects can include one or more of the following. The etch gas is flowed for an etch time and the purge gas is flowed for a purge time that is greater than the etch time. The forming of the source and drain material is conducted in a plurality of deposition cycles that respectively include a first deposition operation comprising simultaneously flowing a deposition gas and an etch composition at a first etch flow rate and a second deposition operation comprising simultaneously flowing the deposition gas and the etch composition at a second etch flow rate, wherein the second etch flow rate is larger than the first etch flow rate. The first deposition operation has a first deposition time, the second deposition operation has a second deposition time that is shorter than the first deposition time, the first etch flow rate is defined by a first etch-deposition ratio, and the second etch flow rate is defined by a second etch-deposition ratio that is greater than the first etch-deposition ratio. The deposition gas includes a phosphorous dopant source gas including an organophosphine having the formula PRₙH₃₋ₙ, n is from 1 to 3, and R is an ethyl group, a propyl group, or a butyl group.

In yet another aspect, a method of substrate processing includes depositing a material on a substrate. The depositing includes flowing a deposition precursor for a deposition time and at a deposition flow rate, and maintaining a deposition pressure. The method includes conducting a first etching operation on the material. The first etching operation includes flowing a first etch precursor for a first etch time and at a first etch flow rate, and maintaining a first etch pressure that is larger than the deposition pressure. The depositing and the first etching operation are sequentially repeated for a first plurality of cycles. The method includes conducting a second etching operation on the material. The second etching operation includes flowing a second etch precursor for a second etch time and at a second etch flow rate greater than the first etch flow rate, and maintaining a second etch pressure. The depositing and the second etching operation are sequentially repeated for a second plurality of cycles that is less than the first plurality of cycles.

Implementations of the aspects can include one or more of the following. The depositing further includes maintaining a deposition pressure, and the first etching operation further includes maintaining a first etch pressure greater than the deposition pressure. The second etching operation further includes maintaining a second etch pressure greater than the deposition pressure, the second etch pressure less than the first etch pressure. The deposition pressure is less than 100 Torr, the first etch pressure is 350 Torr or higher, and the second etch pressure is 100 Torr or less. The first etch pressure is a pressure ratio of the deposition pressure, and the pressure ratio is at least 5.0. The second etch flow rate is a flow ratio of the first etch flow rate, and the flow ratio is at least 1.30. The flow ratio is within a range of 1.40 to 1.60. The depositing, the first etching operation, and the second etching operation respectively include maintaining a temperature of less than 700 degrees Celsius. The deposition precursor flows for a deposition time, the first etch precursor flows for a first etch time that is larger than the deposition time, and the second etch precursor flows for a second etch time larger than the first etch time. The deposition precursor includes a phosphorous dopant source gas comprising an organophosphine having the formula PRₙH₃₋ₙ, n is from 1 to 3, and R is an ethyl group, a propyl group, or a butyl group.

In yet another aspect, a method of substrate processing includes depositing a material on a substrate. The depositing includes flowing a deposition precursor for a deposition time and at a deposition flow rate, and maintaining a deposition pressure. The method includes conducting a first etching operation on the material. The first etching operation includes flowing a first etch precursor for a first etch time and at a first etch flow rate, and maintaining a first etch pressure that is larger than the deposition pressure. The method includes conducting a second etching operation on the material. The second etching operation includes flowing a second etch precursor for a second etch time and at a second etch flow rate greater than the first etch flow rate, and maintaining a second etch pressure that is greater than the deposition pressure and less than the first etch pressure.

Implementations of the aspects can include one or more of the following. The deposition pressure is less than 100 Torr, the first etch pressure is 350 Torr or higher, and the second etch pressure is 100 Torr or less. The first etch pressure is a pressure ratio of the deposition pressure, and the pressure ratio is at least 5.0. The pressure ratio is within a range of 10.0 to 12.0. The second etch pressure is a pressure ratio of the deposition pressure, and the pressure ratio is at least 1.1. The pressure ratio is within a range of 1.15 to 1.35. The depositing and the first etching operation are sequentially repeated for a first plurality of cycles, and the second etching operation is continuously conducted for the second etch time, and the second etch time is at least 200 seconds. The deposition precursor includes a phosphorous dopant source gas including an organophosphine having the formula PRₙH₃₋ₙ, n is from 1 to 3, and R is an ethyl group, a propyl group, or a butyl group.

In yet another aspect, a non-transitory computer readable medium includes instructions that when executed cause a plurality of operations to be conducted. The plurality of operations includes flowing a deposition precursor for a deposition time and at a deposition flow rate, maintaining a deposition pressure, and flowing a first etch precursor for a first etch time and at a first etch flow rate. The plurality of operations includes maintaining a first etch pressure that is larger than the deposition pressure, flowing a second etch precursor for a second etch time and at a second etch flow rate greater than the first etch flow rate, and maintaining a second etch pressure. The deposition precursor includes a phosphorous dopant source gas including an organophosphine having the formula PRₙH₃₋ₙ, n is from 1 to 3, and R is an ethyl group, a propyl group, or a butyl group.

Implementations of the aspects can include one or more of the following. The first etch pressure is a pressure ratio of the deposition pressure, and the pressure ratio is at least 5.0. The flow ratio is within a range of 1.40 to 1.60.

In yet another aspect, a method of substrate processing includes forming a source and drain material on a structure of a substrate, and etching the source and drain material. The etching is conducted in a plurality of etch cycles that respectively include flowing a purge gas and flowing an etch gas to etch the source and drain material.

In yet another aspect, a method of substrate processing includes forming a source and drain material on a structure of a substrate. The forming of the source and drain material is conducted in a plurality of deposition cycles that respectively includes a first deposition operation and a second deposition operation. The first deposition operation includes simultaneously flowing a deposition gas and an etch composition at a first etch flow rate. The second deposition operation includes simultaneously flowing the deposition gas and the etch composition at a second etch flow rate. The second etch flow rate is larger than the first etch flow rate.

In yet another aspect, a non-transitory computer readable medium includes instructions that, when executed, cause a plurality of operations to be conducted. The plurality of operations includes forming a source and drain material on a structure of a substrate, and etching the source and drain material. The etching is conducted in a plurality of etch cycles that respectively include flowing a purge gas, and flowing an etch gas to etch the source and drain material.

In yet another aspect, a method of forming a semiconductor device is provided. The method includes performing a process cycle including an epitaxial deposition process and a selective etchback process subsequent to the epitaxial deposition process. The epitaxial deposition process forms an n-type doped semiconductor layer including an n-type dopant on an exposed surface of a substrate. The selective etchback process selectively removes an amorphous portion of the n-type doped semiconductor layer leaving an epitaxial portion of the n-type doped semiconductor layer. The n-type doped semiconductor layer includes silicon. The method further includes repeating the process cycle for a number of cycles to achieve a targeted thickness. The process cycle deposits the n-typed doped semiconductor layer having a thickness in a range from about 20 Å to about 50 Å.

Implementations of the aspects can include one or more of the following. The epitaxial deposition process includes flowing a phosphorous dopant source gas including an organophosphine having the formula PRₙH₃₋ₙ, n is from 1 to 3, and R is an ethyl group, a propyl group, or a butyl group. The epitaxial deposition process further includes flowing a silicon-containing precursor in a processing chamber. The selective etchback process includes flowing an etchant gas including HCl and GeH4, subsequent to the epitaxial deposition process. The epitaxial deposition process is performed at a first temperature and a first pressure and the selective etchback process is performed at a second temperature and a second pressure, the second temperature and the second pressure is greater than the first temperature and the first pressure. The first temperature is 1150 degrees Celsius or less and the first pressure is 110 Torr or less. The exposed surface of the substrate includes one or more monocrystalline surfaces and one or more non-monocrystalline surfaces, the epitaxial portion of the n-type doped semiconductor layer is selectively formed on the one or more monocrystalline surfaces and the amorphous portion of the n-type doped semiconductor layer is selectively formed on the one or more non-monocrystalline surfaces. The number of cycles is in a range from six to fifteen.

In yet another aspect, a method of forming a semiconductor device is provided. The method includes epitaxially growing an n-type doped semiconductor layer on a pair of opposing sidewall surfaces and a bottom surface, the pair of opposing sidewall surfaces and the bottom surface defining a source/drain cavity. Epitaxially growing the n-type doped semiconductor layer, includes performing a process cycle including an epitaxial deposition process and a selective etchback process subsequent to the epitaxial deposition process. The epitaxial deposition process includes forming the n-type doped semiconductor layer including an n-type dopant on an exposed surface of a substrate. The selective etchback process selectively removes an amorphous portion of the n-type doped semiconductor layer and leaves an epitaxial portion of the n-type doped semiconductor layer. The n-type doped semiconductor layer includes silicon. The method further includes repeating the process cycle for a number of cycles to achieve a targeted thickness. The process cycle deposits the n-typed doped semiconductor layer having a thickness in a range from about 20 Å to about 50 Å.

Implementations of the aspects can include one or more of the following. The epitaxial deposition process includes flowing a phosphorous dopant source gas including an organophosphine having the formula PRₙH₃₋ₙ, n is from 1 to 3, and R is an ethyl group, a propyl group, or a butyl group. The epitaxial deposition process further includes flowing a silicon-containing precursor in a processing chamber. The selective etchback process includes flowing an etchant gas including HCl and GeH4 in the processing chamber, subsequent to the epitaxial deposition process. The epitaxial deposition process is performed at a first temperature and a first pressure and the selective etchback process is performed at a second temperature and a second pressure, the second temperature and the second pressure is greater than the first temperature and the first pressure. The first temperature is 1150 degrees Celsius or less and the first pressure is 110 Torr or less. The exposed surface of the substrate includes one or more monocrystalline surfaces and one or more non-monocrystalline surfaces, the epitaxial portion of the n-type doped semiconductor layer selectively formed on the one or more monocrystalline surfaces and the amorphous portion of the n-type doped semiconductor layer formed on the one or more non-monocrystalline surfaces. The number of cycles is in a range from six to fifteen.

In yet another aspect, a processing system includes one or more processing chambers, and a system controller configured to cause the processing system to perform (a) a pre-clean process on exposed surfaces of a semiconductor structure, the semiconductor structure comprising a first semiconductor region, a second semiconductor region separated from the first semiconductor region by a trench, and a dielectric layer over at least a portion of the first semiconductor region and the second semiconductor region, (b) a first deposition process to form a phosphorous-doped amorphous silicon-containing layer on the exposed surfaces of the semiconductor structure, (c) an etch process to remove portions of the phosphorous-doped amorphous silicon-containing layer from sidewalls of a trench. The phosphorous-doped amorphous silicon layer can be formed using a dopant source including tert-butyl phosphine (C4H11P).

In yet another aspect, a non-transitory computer readable medium has stored thereon instructions, which, when executed by a processor, causes the process to perform operations of the above apparatus and/or method.

### BRIEF DESCRIPTION OF THE DRAWINGS

So that the manner in which the above-recited features of the present disclosure can be understood in detail, a more particular description of the disclosure, briefly summarized above, may be had by reference to implementations, some of which are illustrated in the appended drawings. It is to be noted, however, that the appended drawings illustrate only exemplary implementations and are therefore not to be considered limiting of scope, and may admit to other equally effective implementations.

FIG. 1 is a schematic top view of a multi-chamber processing system in accordance with one or more implementations of the present disclosure.

FIG. 2 is a cross-sectional view of a processing chamber in accordance with one or more implementations of the present disclosure.

FIG. 3 is a schematic block diagram view of a method of substrate processing, according to one or more embodiments.

FIGS. 4A-4D are schematic partial cross-sectional views of the method conducted in relation to a semiconductor device structure, according to one or more embodiments.

FIGS. 5A-5B are schematic partial cross-sectional views of the method conducted in relation to the semiconductor device structure, according to one or more embodiments.

FIG. 6 is a schematic block diagram view of a method of substrate processing, according to one or more embodiments.

FIG. 7 is a schematic partial cross-sectional view of a semiconductor device structure, according to one or more embodiments.

FIGS. 8A-8F are schematic side views of cyclic deposition-etch operations, according to one or more embodiments.

FIG. 9 is schematic table view of a table of parameters that can be used in the method, according to one or more embodiments.

FIG. 10 is an exemplary flow chart of a method for forming a semiconductor device structure in accordance with one or more implementations of the present disclosure.

FIGS. 11A-11D are schematic side views of various stages of manufacturing a semiconductor device structure according to the method of FIG. 10 in accordance with one or more implementations of the present disclosure.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

The present disclosure generally relates to semiconductor devices and methods for manufacturing semiconductor devices. More particularly, the disclosure relates to systems and methods of bottom-up epitaxial growth within a semiconductor structure.

Multi-gate metal-oxide-semiconductor field-effect transistors (MOSFETs), such as double-gate field-effect transistors (FinFETs), silicon-on-insulator (SOI) tri-gate MOSFETs, and gate all around (GAA) FETs, that incorporate more than one gate into a single device and are thus more scalable than the conventional planar bulk MOSFET, pose challenges in manufacturability due to their three-dimensional (3D) designs and small sizes. In architectures for sub 10-15 nm technology nodes, such as GAA FETs, in which a gate is placed on two or all four sides of a silicon-based channel, parasitic or external resistance significantly impacts device performance. In such devices, a source/drain region may be formed within a trench by an epitaxy process. However, increased variation of critical dimensions (e.g., line width) has been observed in such devices, due to inner surfaces of the trench having different materials (e.g., silicon (Si) and silicon nitride (Si₃N₄)) during the epitaxy process. This non-uniformity leads to varying growth rates over the inner surfaces of the trench in the epitaxy process. Accordingly, the varying growth rates can lead to the formation of defects such as twins, stacking faults, or voids in the source/drain region. The presence of defects in source/drain regions can drastically increase contact resistance.

In one or more embodiments, a cyclic epitaxial deposition process for forming n-type doped semiconductor features is provided. The cyclic epitaxial deposition process includes an epitaxial deposition process and a selective etchback process subsequent to the epitaxial deposition process. The cyclic epitaxial deposition process provides for precise thickness control per each cycle. The selective etchback process selectively removes unwanted amorphous portions of the n-type doped semiconductor layer which enables bottom-up epitaxial growth of the features with reduced defects and improved performance. In some embodiments, the epitaxial deposition process includes flowing a phosphorous dopant source gas comprising an organophosphine compound having the formula PRₙH₃₋ₙ, n is from 1 to 3, and R is an ethyl group, a propyl group, or a butyl group. The organophosphine dopant source gases have been found to increase the levels of phosphorous dopant in the n-type doped silicon-containing layer in comparison with phosphine gas. In addition, organophosphine dopant source gases have been found to suppress nucleation on dielectric surfaces which reduces the formation of undesirable amorphous silicon on dielectric surfaces such as inner spacers. Further, the organophosphine dopant source gases enable deposition at lower temperatures in comparison with phosphine dopant source gases. Not to be bound by theory, but it is believed that hydrogen scavenging performed by the leaving groups of the organophosphine dopant source gases reduces the barrier for low temperature growth.

The embodiments described herein are applicable to Fin Field-Effect Transistors (FinFETs) and nanostructure field-effect transistors (nano-FET) including vertically stacked lateral nanowires (NW)/nanosheets (NS) Gate-All-Around (GAA) FET devices. In addition, the techniques described herein can be implemented with a gate-first process in which the source and drain are formed after the gate is formed or a gate-last process in which the source and drain are formed prior to the gate, sometimes referred to as a replacement metal gate or RMG process.

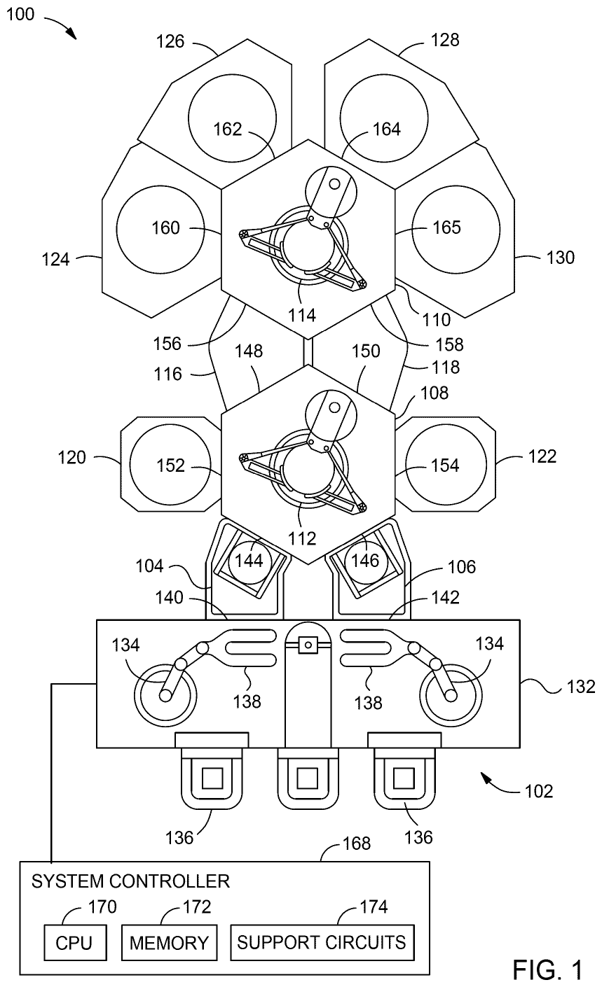

FIG. 1 is a schematic top view of a multi-chamber processing system 100, according to one or more implementations of the present disclosure. The multi-chamber processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the multi-chamber processing system 100 can be processed in and transferred between the various chambers without exposing the substrates to an ambient environment exterior to the multi-chamber processing system 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the multi-chamber processing system 100. Accordingly, the multi-chamber processing system 100 may provide an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 165 coupled to processing chambers 124, 126, 128, 130. The ports 144, 146, 148, 150, 152, 154, 156, 158, 160, 162, 164, 165 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port can be closed.

The load lock chambers 104, 106, transfer chambers 108, 110, holding chambers 116, 118, and processing chambers 120, 122, 124, 126, 128, 130 may be fluidly coupled to a gas and pressure control system. The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 165 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In one or more examples, the processing chamber 120 can be capable of performing an etch process, the processing chamber 122 can be capable of performing a cleaning process, the processing chamber 124 can be capable of performing a selective removal process, and the processing chambers 126, 128, 130 can be capable of performing respective epitaxial growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126, 128, or 130 may be a Centura™ Epi chamber available from Applied Materials of Santa Clara, Calif. The present disclosure contemplates that the deposition operations and the etching operations described herein can be conducted in the same chamber (such as in the same deposition chamber) or can be conducted in multiple chambers.

A system controller 168 is coupled to the multi-chamber processing system 100 for controlling the multi-chamber processing system 100 or components thereof. For example, the system controller 168 may control the operation of the multi-chamber processing system 100 using a direct control of the chambers 104, 106, 108, 110, 116, 118, 120, 122, 124, 126, 128, 130 of the multi-chamber processing system 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the multi-chamber processing system 100.

The system controller 168 generally includes a central processing unit (CPU) 170, memory 172, and support circuits 174. The CPU 170 may be one of any form of a general-purpose processor that can be used in an industrial setting. The memory 172, or non-transitory computer-readable medium, is accessible by the CPU 170 and may be one or more of memory such as read only memory (ROM) (e.g., electrically erasable programmable read-only memory (EEPROM)), flash memory (e.g., flash drive), floppy disk, hard disk, random access memory (RAM) (e.g., non-volatile random access memory (NVRAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), or any other form of digital storage, local or remote. The support circuits 174 are coupled to the CPU 170 and may comprise cache, clock circuits, input/output subsystems, power supplies, and the like. The various methods disclosed herein (such as the method 300, the method 600, and/or the method 1000) may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

The instructions stored in the memory 172 of the system controller 168 can include one or more machine learning/artificial intelligence algorithms that can be executed in addition to the operations described herein. As an example, a machine learning/artificial intelligence algorithm executed by the system controller 168 can generate, prioritize, accept, and/or reject signal profiles and/or data (such as metrology data and/or substrate map data) used in relation to the method 300, the method 600, and/or the method 1000. The machine learning/artificial intelligence algorithm can account for previous operational runs to monitor and update the signal profiles and/or data. The machine learning/artificial intelligence algorithm can optimize process parameter(s) of process recipes. The one or more machine learning/artificial intelligence algorithms can use, for example, a regression model (such as a linear regression model) or a clustering technique to estimate optimized parameters and/or optimized values for signal profiles and/or data. The algorithm(s) can be unsupervised or supervised. In one or more implementations, the system controller 168 automatically conducts the operations described herein without the use of one or more machine learning/artificial intelligence algorithms. In one or more implementations, the system controller 168 compares measurements to data in a look-up table and/or a library to optimize process parameters. The system controller 168 can store measurements as data in the look-up table and/or the library.

Other processing systems can be in other configurations. For example, more or fewer processing chambers may be coupled to a transfer apparatus. In the illustrated example, the transfer apparatus includes the transfer chambers 108, 110 and the holding chambers 116, 118. In one or more examples, more or fewer transfer chambers (e.g., one transfer chamber) and/or more or fewer holding chambers (e.g., no holding chambers) may be implemented as a transfer apparatus in a processing system.

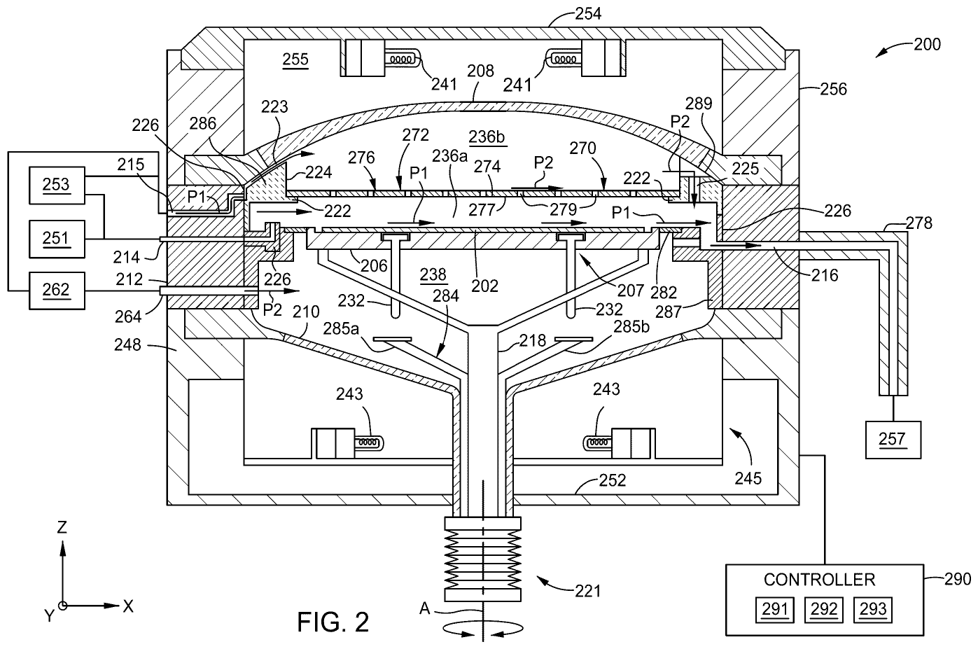

FIG. 2 is a cross-sectional view of a processing chamber 200, according to one or more implementations. In one or more implementations, the processing chamber 200 is configured to conduct an epitaxial (Epi) deposition process as detailed below. The processing chamber 200 may be the processing chamber 126, 128, or 130 shown in FIG. 1.

FIG. 2 is a partial schematic side cross-sectional view of a processing chamber 200 in accordance with one or more embodiments of the present disclosure. The processing chamber 200 provides one example of a process chamber in which the pulse-etch-purge process can be performed. The processing chamber 200 is a deposition chamber. In one or more embodiments, the processing chamber 200 is an epitaxial deposition chamber. In one or more embodiments, the processing chamber 200 is utilized to grow an epitaxial film on a substrate 202. The processing chamber 200 creates a crossflow of precursors across a top surface of the substrate 202. The processing chamber 200 is shown in a processing condition in FIG. 2. The processing chamber 200 may be the processing chamber 124, 126, 128, or 130 shown in FIG. 1.

The processing chamber 200 includes an upper body 256, a lower body 248 disposed below the upper body 256, a flow module 212 disposed between the upper body 256 and the lower body 248. The upper body 256, the flow module 212, and the lower body 248 form a chamber body. Disposed within the chamber body is a substrate support 206, an upper plate 208 (such as an upper window and/or an upper dome), a lower plate 210 (such as a lower window and/or a lower dome), a plurality of upper heat sources 241, and a plurality of lower heat sources 243. As shown, a controller 290 is in communication with the processing chamber 200 and is used to control processes and methods, such as the operations of the methods described herein. The present disclosure contemplates that each of the heat sources described herein can include one or more of: lamp(s), resistive heater(s), light emitting diode(s) (LEDs), and/or laser(s). The present disclosure contemplates that other heat sources can be used.

The substrate support 206 is disposed between the upper plate 208 and the lower plate 210. The substrate support 206 includes a support face that supports the substrate 202. The plurality of upper heat sources 241 are disposed between the upper window and a lid 254. The plurality of upper heat sources 241 form a portion of the upper heat source module 255. The lid 254 may include a plurality of sensors disposed therein or thereon for measuring the temperature within the processing chamber 200. The plurality of lower heat sources 243 are disposed between the lower plate 210 and a floor 252. The plurality of lower heat sources 243 form a portion of a lower heat source module 245. In one or more embodiments, the upper plate 208 is an upper dome and is formed of an energy transmissive material, such as quartz. In one or more embodiments, the lower plate 210 is a lower dome and is formed of an energy transmissive material, such as quartz. A pre-heat ring 282 is disposed outwardly of the substrate support 206. A stop 284 includes a plurality of arms 285a, 285b that each include a lift pin stop on which at least one of the lift pins 232 can rest when the substrate support 206 is lowered (e.g., lowered from a process position to a transfer position).

The internal volume has the substrate support 206 disposed therein. The substrate support 206 includes a top surface on which the substrate 202 is disposed. The substrate support 206 is attached to a shaft 218. The shaft 218 is connected to a motion assembly 221. The motion assembly 221 includes one or more actuators and/or adjustment devices that provide movement and/or adjustment for the shaft 218 and/or the substrate support 206.

The substrate support 206 may include lift pin perforations 207 disposed therein. The lift pin perforations 207 are sized to accommodate a lift pin 232 for lifting of the substrate 202 from the substrate support 206 either before or after a deposition process is performed.

A chamber kit 270 includes a plate apparatus 272. The plate apparatus 272 includes an isolation plate 274 having a first outer face 276 and a second outer face 277 opposing the first outer face 276. The second outer face 277 faces the substrate support 206. The isolation plate 274 can have one or more holes 279 extending from the first outer face 276 to the second outer face 277.

The chamber body includes a first liner 286 and a second liner 287. The second liner 287 is disposed below the first liner 286. The pre-heat ring 282 is supported on a ledge of the second liner 287. The first liner 286 includes a curved section 289 (e.g., an annular section). One or more inlet openings 223 extending to an inner surface 224 of the curved section 289 are on a first side of the first liner 286, and one or more second outlet openings 225 are on a second side of the first liner 286. The one or more inlet openings 223 can be between the first liner 286 and the upper plate 208. The first liner 286 includes one or more ledges 222 sized and shaped to support an outer region of the plate apparatus 272.

In the embodiment shown in FIG. 2, a lowermost end of the plate apparatus 272 is aligned above a lowermost end of the first liner 286. In one or more embodiments, as shown in FIG. 2, the lowermost end of the plate apparatus 272 is part of the second outer face 277, and the lowermost end of the first liner 286 is part of an extension.

At least part of the plate apparatus 272 is in the shape of a disc, and at least part of the curved section 289 is in the shape of a ring. It is contemplated, however, that the plate apparatus 272 and/or the curved section 289 can be in the shape of a rectangle, or other geometric shapes. The plate apparatus 272 at least partially fluidly isolates an upper portion 236b of an internal volume from a lower portion 236a of the internal volume. The lower portion 236a is a processing volume. The plate apparatus 272 at least partially defines the processing volume between the plate apparatus 272 and the substrate support 206.

In one or more embodiments, the isolation plate 274 is omitted, and the processing volume spans the open space between the substrate 202 and the upper plate 208.

The flow module 212 (which can define at least part of one or more sidewalls of the processing chamber 200) includes one or more first gas inlets 214 in fluid communication with the lower portion 236a (e.g., the processing volume) of the internal volume. The flow module 212 includes one or more second inlet openings 215 in fluid communication with the upper portion 236b of the internal volume. The one or more first gas inlets 214 are in fluid communication with one or more flow gaps between the first liner 286 and the second liner 287. One or more inject blocks 226 having one or more flow openings formed therein can be disposed in one or more flow gaps between the first liner 286 and the second liner 287. The one or more second gas inlets 215 are in fluid communication with the one or more inlet openings 223 above the first liner 286. The one or more first gas inlets 214 are fluidly connected to one or more process gas sources 251 and one or more etchant gas sources 253. The plurality of purge gas inlets 264 are fluidly connected to one or more purge gas sources 262. The one or more gas exhaust outlets 216 are fluidly connected to an exhaust pump 257. One or more process gases supplied using the one or more process gas sources 251 can include one or more reactive gases (such as one or more of silicon-containing, phosphorus-containing, and/or germanium-containing gases, and/or one or more carrier gases (such as one or more of nitrogen (N₂) and/or hydrogen (H₂)). One or more purge gases supplied using the one or more purge gas sources 262 can include one or more inert gases (such as one or more of argon (Ar), helium (He), and/or nitrogen (N₂)). One or more cleaning gases and/or etchant gases supplied using the one or more etchant gas sources 253 can include one or more of hydrogen and/or chlorine (such as hydrochloric acid (HCl) and/or chlorine gas (Cl₂)). The HCl and the chlorine gas can be injected at different locations along the processing chamber. In one or more embodiments, the HCl and/or Cl2 can be injected into the lower portion 236a via the one or more first gas inlets 214. In one or more embodiments, the HCl and/or Cl2 can be injected into the upper portion 236b via the one or more second gas inlets 215, and travel through the holes 279 in the isolation plate 274 into the lower portion 236a. In one or more embodiments, the one or more process gases include silicon hydrides (such as one or more silanes and/or one or more chlorinated silanes), germanium (such as germane (GeH₄)), boron (such as diborane (B₂H₆)), and/or phosphine (PH₃).

The one or more gas exhaust outlets 216 are further connected to or include an exhaust system 278. The exhaust system 278 fluidly connects the one or more gas exhaust outlets 216 and the exhaust pump 257. The exhaust system 278 can assist in the controlled deposition of a layer on the substrate 202. The exhaust system 278 is disposed on the opposite side of the processing chamber 200 relative to the flow module 212.

During a deposition operation (e.g., an epitaxial growth operation), the one or more process gases P1 flow through the one or more first gas inlets 214, through the one or more gaps, and into the lower portion 236a to flow horizontally over the substrate support 206 and the substrate 202 and to the one or more gas exhaust outlets 216. During the deposition operation, one or more purge gases P2 flow through the one or more second gas inlets 215, through the one or more inlet openings 223 of the first liner 286, and into the upper portion 236b. The one or more purge gases P2 flow simultaneously with the flowing of the one or more process gases P1. The flowing of the one or more purge gases P2 through the upper portion 236b facilitates reducing or preventing flow of the one or more process gases P1 into the upper portion 236b that would contaminate the upper portion 236b. The one or more process gases P1 are exhausted through exhaust gaps between the first liner 286 and the second liner 287, and through the one or more gas exhaust outlets 216. The one or more purge gases P2 are exhausted through the one or more second outlet openings 225, through the same exhaust gaps between the first liner 286 and the second liner 287, and through the same one or more gas exhaust outlets 216 as the one or more process gases P1. The present disclosure contemplates that that one or more purge gases P2 can be separately exhausted through one or more second gas exhaust outlets that are separate from the one or more gas exhaust outlets 216.

The present disclosure also contemplates that one or more purge gases can be supplied to the purge volume 238 (through the plurality of purge gas inlets 264) during the deposition operation and exhausted from the purge volume 238.

The controller 290 generally includes a central processing unit (CPU) 291, memory 292, and support circuits 293. The CPU 291 may be one of any form of a general-purpose processor that can be used in an industrial setting. The memory 292, or non-transitory computer-readable medium, is accessible by the CPU 291 and may be one or more of memory such as read only memory (ROM) (e.g., electrically erasable programmable read-only memory (EEPROM)), flash memory (e.g., flash drive), floppy disk, hard disk, random access memory (RAM) (e.g., non-volatile random access memory (NVRAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), or any other form of digital storage, local or remote. The support circuits 293 are coupled to the CPU 291 and may include cache, clock circuits, input/output subsystems, power supplies, and the like. The various methods disclosed herein (such as the method 300, the method 600, and/or the method 1000) may generally be implemented under the control of the CPU 291 by the CPU 291 executing computer instruction code stored in the memory 292 (or in memory of a particular processing chamber) as, for example, a software routine. When the computer instruction code is executed by the CPU 291, the CPU 291 controls the chambers to perform processes in accordance with the various methods.

The instructions stored in the memory 292 of the controller 290 can include one or more machine learning/artificial intelligence algorithms that can be executed in addition to the operations described herein. As an example, a machine learning/artificial intelligence algorithm executed by the controller 290 can generate, prioritize, accept, and/or reject signal profiles and/or data (such as metrology data and/or substrate map data) used in relation to the method 300, the method 600, and/or the method 1000. The machine learning/artificial intelligence algorithm can account for previous operational runs to monitor and update the signal profiles and/or data. The machine learning/artificial intelligence algorithm can optimize process parameter(s) of process recipes. The one or more machine learning/artificial intelligence algorithms can use, for example, a regression model (such as a linear regression model) or a clustering technique to estimate optimized parameters and/or optimized values for signal profiles and/or data. As an example, the one or more machine learning/artificial intelligence algorithms can optimize the exemplary parameter values described herein (such as the method 300, the method 600, and/or the method 1000). The algorithm(s) can be unsupervised or supervised. In one or more embodiments, the controller 290 automatically conducts the operations described herein without the use of one or more machine learning/artificial intelligence algorithms. In one or more embodiments, the controller 290 compares measurements to data in a look-up table and/or a library to optimize process parameters. The controller 290 can store measurements as data in the look-up table and/or the library.

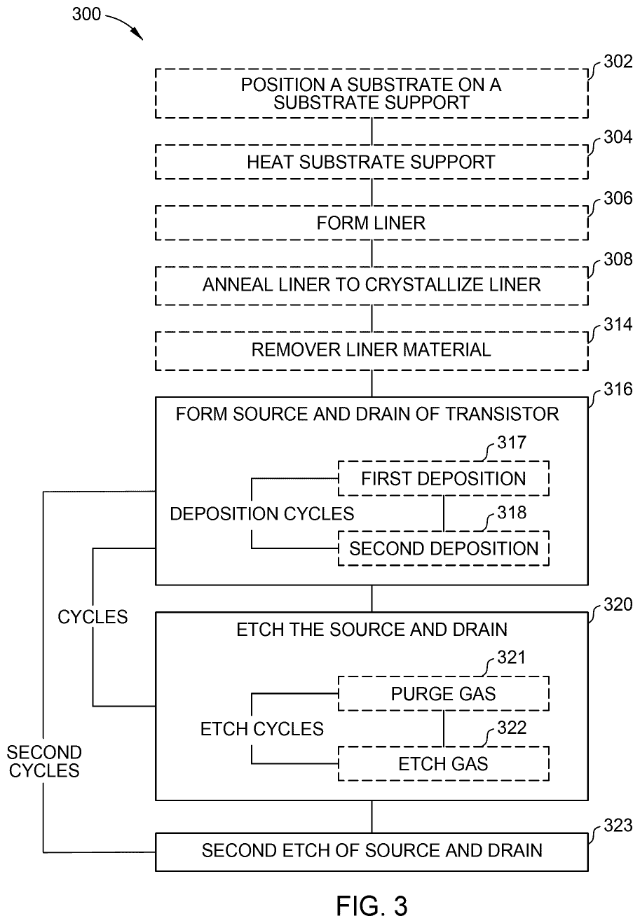

FIG. 3 is a schematic block diagram view of a method 300 of substrate processing, according to one or more embodiments.

Optional operation 302 includes positioning a substrate on a substrate support in a processing volume of a processing chamber. In one or more embodiments, the positioning includes moving a substrate support and/or a plurality of lift pins relative to each other to land the substrate on the substrate support.

Optional operation 304 of the method 300 includes heating the substrate support and/or the substrate in the processing volume to a target temperature.

Optional operation 306 includes forming a liner on a structure on a substrate. The liner includes silicon, and the forming includes a formation temperature. For example, the formation temperature can be set for the forming (e.g., deposition) of the liner. The forming includes flowing a deposition precursor. The deposition precursor includes silicon. For example, the deposition precursor can include one or more silanes. Other materials are contemplated for the deposition precursor. In one or more embodiments, the deposition precursor includes silicon and/or phosphorus, such as to form silicon film or silicon phosphorus (SiP) film, or the deposition precursor includes silicon, germanium, and/or boron, such as to form silicon-germanium-boron (SiGeB) film. In one or more embodiments, the forming of the liner includes a formation temperature of 500 degrees Celsius or less, such as 400 degrees Celsius or less. In one or more embodiments, the formation temperature is within a range of 200 degrees Celsius to 1,300 degrees Celsius, such as 600 degrees Celsius to 850 degrees Celsius. The formed liner can be crystalline film that is crystalline at the formation temperature, or amorphous film that can be crystallized with a crystalline substrate as a template upon annealing at a higher temperature (such as in optional operation 308).

The formed liner can include a promotion material that promotes the crystallization of the amorphous liner in operation 308. In one or more embodiments, the promotion material includes one or more of: germanium, gallium, tin, or arsenic. An atomic percentage of the promotion material in the amorphous liner is 10% or less. In one or more embodiments, the atomic percentage is 5% or less, such as 2% or less. In one or more embodiments, n-type epitaxial deposition is conducted, and the atomic percentage of the germanium in the amorphous liner is 10% or less. In one or more embodiments, p-type epitaxial deposition is conducted, and the atomic percentage of the germanium in the amorphous liner is within a range of 5% to 30%.

The formation of the liner in operation 306 can include one or more functions of operation 316 and/or operation 320 described below. The liner can be crystalline at formation.

Optional operation 308 includes annealing the amorphous liner to crystallize the amorphous liner into a crystalline liner. In one or more embodiments, the annealing includes ramping the formation temperature to an anneal temperature at a ramp rate. The ramp rate is less than 3.0 degrees Celsius-per-second. In one or more embodiments, the ramp rate is less than 1.0 degrees Celsius-per-second. In one or more embodiments, the ramp rate is within a range of 0.1 degrees Celsius-per-second to 0.5 degrees Celsius-per-second. In one or more embodiments, the annealing includes soaking the amorphous liner at the anneal temperature after the formation temperature is ramped to the anneal temperature. As an example, the soaking can include maintaining the anneal temperature for a time period to bake the liner.

The formation temperature is less than 500 degrees Celsius, and the anneal temperature is greater than 650 degrees Celsius. In one or more embodiments, the formation temperature 400 degrees Celsius or less, such as 100 degrees Celsius to 400 degrees Celsius. In one or more embodiments, the anneal temperature is within a range of 650 degrees Celsius to 850 degrees Celsius, such as about 700 degrees Celsius.

Optional operation 312 includes doping the crystallized liner with a dopant material. In one or more embodiments, the doping is conducted during the deposition in operation 306. In one or more embodiments, the doping is conducted after the annealing of operation 308. In one or more embodiments, the doping is conducted before and/or after the annealing of operation 308. The dopant material includes one or more Group III and/or Group V elements. In one or more embodiments, the dopant material includes phosphorus and/or boron. Other elements are contemplated for the dopant material.

Optional operation 314 includes removing liner material. In one or more embodiments, the liner material is removed from a plurality of cap layers of the structure. In one or more embodiments, the removing can include etching, such as a halide etch. An etch material can include, for example, hydrochloric acid (HCl) and/or chlorine gas (Cl₂). Other etch materials are contemplated. The liner material that is removed can be amorphous liner material that is not crystallized in operation 308.

Operation 316 includes forming source and drain material on the structure of the substrate. The source and drain material is part of a transistor. If the liner is formed in operation 306, the source and drain material can be formed on the liner. The forming can include flowing a deposition gas. The deposition gas can include, such as a precursor that includes one or more silicon containing gases (such as one or more silicon-hydrogen gases) and/or one or more germanium containing gases. In one or more embodiments, the deposition gas includes one or more of: silane (SiH₄), dichlorosilane (SiH₂Cl₂), disilane (Si₂H₆), trisilane (Si₃H₈), tetrasilane (Si₄H₁₀), and/or one or more other silicon containing materials. In one or more embodiments, the deposition gas includes one or more of: germane (GeH4), digermane (Ge2H6), and/or one or more other germanium containing materials.

The forming of the source and drain material can be conducted in a plurality of deposition cycles that respectively include a first deposition operation 317 and a second deposition operation 318. The first deposition operation 317 includes simultaneously flowing the deposition gas at a deposition flow rate and an etch composition at a first etch flow rate. The second deposition operation 318 includes simultaneously flowing the deposition gas and the etch composition at a second etch flow rate. The present disclosure contemplates that the deposition gas and the etch composition can be pulsed simultaneously. The second etch flow rate is larger than the first etch flow rate. The first etch flow rate and the second etch flow rate respectively are a ratio of the deposition flow rate, and the ratio is less than 0.20. In one or more embodiments, the ratio is within a range of 0.07 to 0.12. In one or more embodiments, the ratio is less than 0.20 when the deposition gas includes dichlorosilane. Other values are contemplated for the ratio. For example, the ratio can be 0.20 or higher, such as 1.0, 2.0, or up to 20.0 or higher. In one or more embodiments, the ratio is 0.20 or higher when the deposition gas includes silane or disilane.

The second etch flow rate is a second ratio of the first etch flow rate. In one or more embodiments, the second ratio is greater than 1.0 and equal to or lesser than 2.0, such as equal to or lesser than 1.4. The second deposition operation 318 can be initiated upon the ending of the first deposition operation 317 such that a purge flow is omitted between the first deposition operation 317 and the second deposition operation 318.

The first etch flow rate of the first deposition operation 317 has a first etch-deposition ratio (e.g., a ratio of the first etch flow rate to the deposition flow rate), and the second etch flow rate of the second deposition operation 318 has a second etch-deposition ratio (e.g., a ratio of the second etch flow rate to the deposition flow rate) that is greater than the first etch-deposition ratio. The first deposition operation 317 has a first deposition time, and the second deposition operation 318 has a second deposition time that is shorter than the first deposition time. In one or more embodiments, the second deposition time is 3.0 seconds or less, such as about 2.0 seconds. In one or more embodiments, the first deposition time is at least 4.0 seconds, such as about 5.0 seconds. In one or more embodiments, the deposition flow rate is at least 300 sccm, such as 400 sccm or higher. In one or more embodiments, the first etch flow rate is less than 50 sccm, such as within a range of 35 sccm to 45 sccm. In one or more embodiments, the second etch flow rate is less than 60 sccm, such as within a range of 46 sccm to 55 sccm. The first deposition operation 317 and the second deposition operation 318 can be conducted for at least 3 deposition cycles, for example at least 10 deposition cycles, such as 10 to 40 deposition cycles. The respective deposition cycles can each include a pulse of the first deposition operation 317 and a pulse of the second deposition operation 318. The respective deposition cycles of operations 317, 318 can respectively deposit source and drain material having an overall thickness of less than 30 Angstroms, for example 20 Angstroms or less, such as about 15 Angstroms. The first deposition operation 317 deposits a larger thickness than the second deposition operation 318. In one or more embodiments, the first deposition operation 317 deposits at a thickness ratio of at least 2:1 (such as about 3:1) relative to the second deposition operation 318.

The present disclosure contemplates that the deposition cycles of operations 317, 318 can be omitted, and the forming of operation 316 can include the flowing of the deposition gas. For example, the forming of operation 316 can include nonselective deposition conducted at the formation temperature of 500 degrees Celsius or less, such as 400 degrees Celsius or less. As an example, nonselective deposition can include flowing of deposition gas without the flow of an etchant gas, and the etchant gas can flow subsequently in operation 320.

Operation 320 includes etching the source and drain material. The etching is conducted in a plurality of etch cycles that respectively include flowing a purge gas (at operation 321) and flowing an etch gas (at operation 322) to etch the source and drain material. In one or more embodiments, the purge gas includes hydrogen (H₂). Other purge gases (such as argon (Ar) and/or nitrogen (N₂)) are contemplated for the purge gas. The purge gas of operation 321 flows at a higher flow rate than the etch gas of operation 322. In one or more embodiments, the etch gas flows at a flow rate of at least 500 sccm, such as about 600 sccm. The etch gas is flowed for an etch time and the purge gas is flowed for a purge time that is greater than the etch time. The purge gas flowing of operation 321 and the etch gas flowing of operation 322 can be conducted for at least 3 etch cycles, such as 10 to 40 etch cycles. The respective etch cycles can each include a pulse of operation 321 and a pulse of operation 322. Operation 320 can be conducted with continuous etch gas by skipping (e.g., omitting) the purge operation 321.

The etch gas includes one or more of: hydrochloric acid (HCl), chlorine gas (Cl₂), hydrogen bromide (HBr), phosphorus trichloride (PCl₃), arsenic trichloride (AsCl₃), germanium trichloride (GeCl₄), and/or one or more other etch materials. In one or more embodiments, the etch time is 5.0 seconds or less, such as 3.0 seconds or less, such as about 2.0 seconds. In one or more embodiments, the purge time is 5.0 seconds or less. In one or more embodiments, the purge time is at least 4.0 seconds, such as about 5.0 seconds. In one or more embodiments, the etch gas of operation 320 includes HCl and Cl₂ co-flowed in a carrier gas (such as nitrogen (N₂) gas). An HCl flow rate of the HCl is larger than a Cl₂ flow rate of the Cl₂. In one or more embodiments, the HCl flow rate is a ratio of the Cl₂ flow rate, and the ratio is at least 5.0, such as at least 10.0. The co-flow of the HCl and Cl₂ can be used and/or adjusted to selectively deposit source and drain material having a net crystalline deposition along the trenches. The co-flow of the HCl and Cl₂ can be used to enhance the selectivity of the liner deposited at a formation temperature of 500 degrees Celsius or less—as described in relation to optional operation 306.

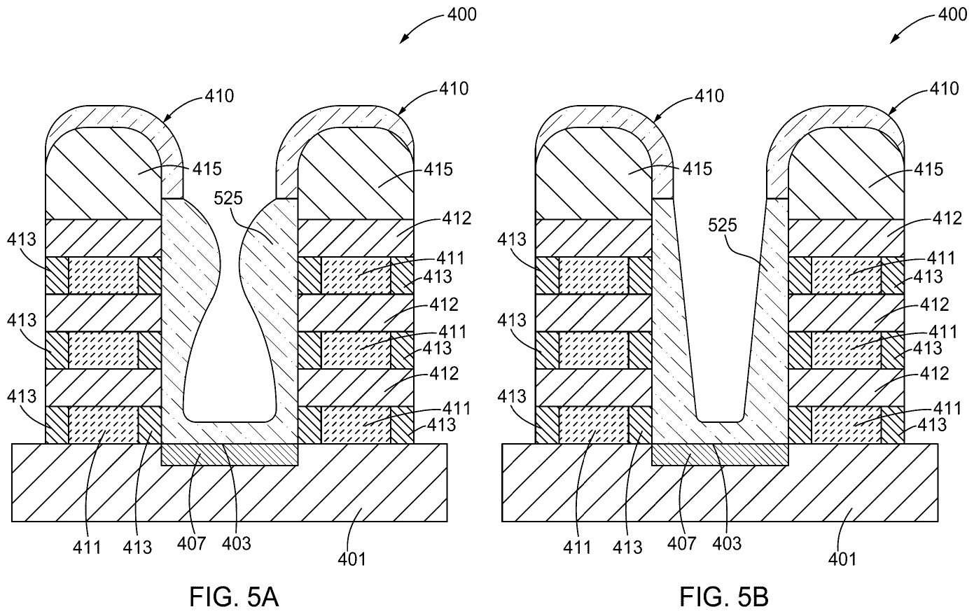

Optional operation 323 includes a second etching of the source and drain material, which includes flowing a second etch gas. In one or more embodiments, the etch gas flow of operation 320 includes HCl and the second etch gas flow of operation 323 includes Cl₂. The present disclosure contemplates that the HCl can be used in the etching of the deposition-etch cycles of operations 316, 320, and the Cl₂ can be used as a continuous etch in operation 323. The present disclosure also contemplates that Cl₂ can be used in operation 322. Operation 320 and operation 323 can be used for selective deposition and/or to form source and drain material having a V-shaped surface profile or a U-shaped surface profile (as shown in FIG. 5B, for example). For example, the formation of the V-shaped or U-shaped surface profile can include conducting the operations 320, 323 after the liner is deposited at a formation temperature of 500 degrees Celsius or less—as described in relation to optional operation 306.

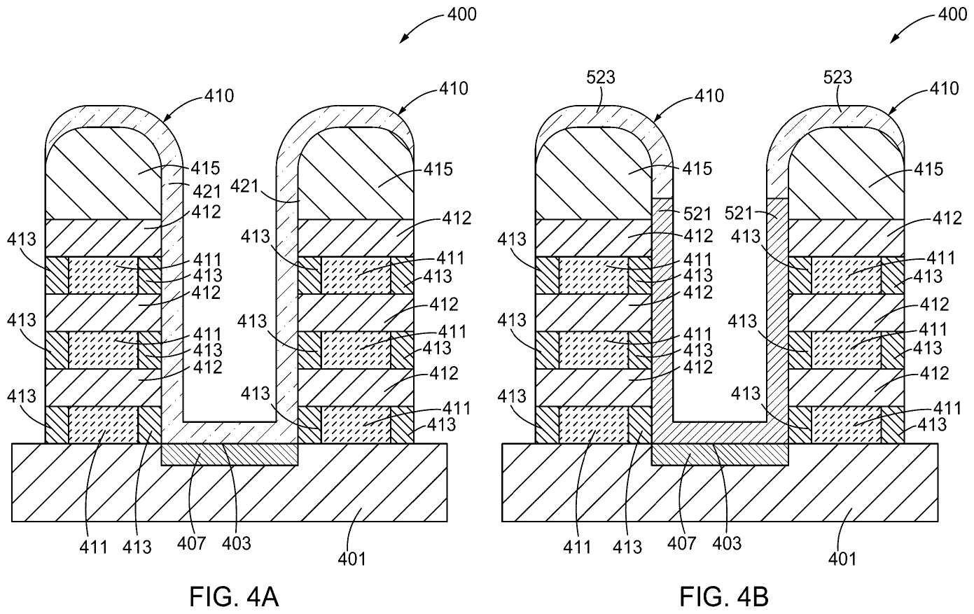

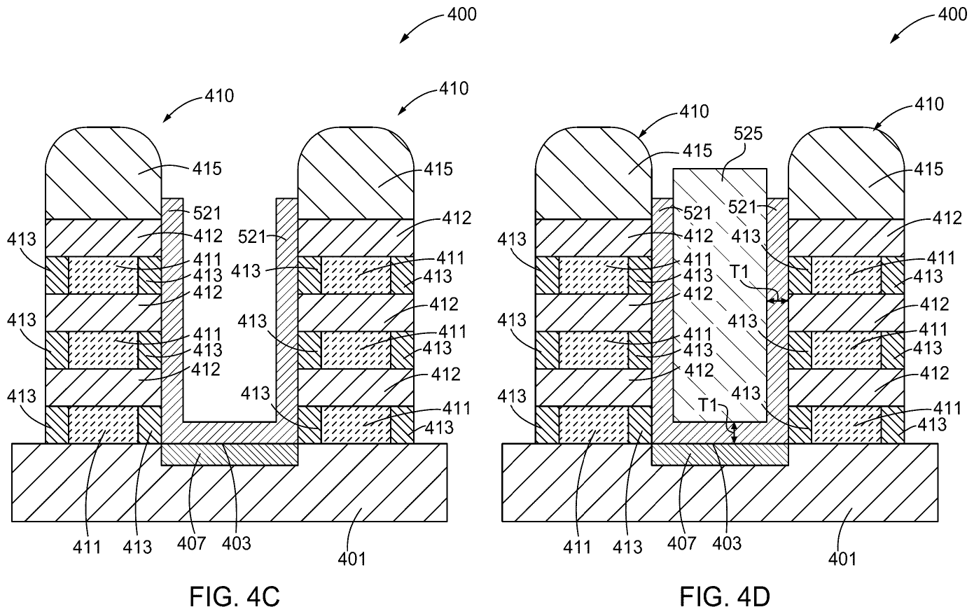

The forming of operation 316 and the etching of operation 320 can be sequentially repeated for a plurality of cycles. The respective cycles can conduct the deposition of operation 316 in a non-pulsed manner and the etching of operation 320 in a non-pulsed manner. The respective cycles can include the pulsed deposition cycles of operations 317, 318 and/or the pulsed etch cycles of operations 321, 322. In one or more embodiments, the respective cycles include both the pulsed deposition cycles and the pulsed etch cycles. In one or more embodiments, the respective cycles include non-pulsed deposition of operation 316 and the pulsed etch cycles of operations 321, 322. In one or more embodiments, the respective cycles include non-pulsed etching of operation 320 and the pulsed deposition cycles of operations 317, 318. A processing volume can be maintained at a pressure of 700 Torr or less, such as 600 Torr or less, for the forming of operation 316 and/or the etching of operation 320. In one or more embodiments, the pressure is 300 Torr or less. The present disclosure contemplates that the second etching of operation 323 can be repeated. In one or more embodiments, a first dep-etch sequence includes the operation 316 and the operation 320 sequentially conducted for the plurality of cycles, and then a second dep-etch sequence includes the operation 316 and the operation 323 sequentially conducted for a plurality of second cycles, where the etch gas in operation 316 includes HCl and the second etch gas in operation 320 includes Cl₂. In one or more embodiments, the first dep-etch sequence and the second dep-etch sequence are conducted after the liner is deposited at a formation temperature of 500 degrees Celsius or less—as described in relation to optional operation 306. The first dep-etch sequence can have a higher deposition-to-etch ratio than the second dep-etch sequence. For example, the first dep-etch sequence can be deposition dominant to bridge the bottom layer 407 (FIG. 4A), and the second dep-etch sequence can be etch dominant to facilitate improved selectivity and/or to facilitate an etch shape (such as to facilitate a source and drain material having a V-shaped surface profile or a U-shaped surface profile, for example).

The present disclosure contemplates that subject matter described for the second etching of operation 323 can be used in the flowing of the etch gas in operation 322.

FIGS. 4A-4D are schematic partial cross-sectional views of the method 300 conducted in relation to a semiconductor device structure 400, according to one or more embodiments.

The semiconductor device structure 400 can be made, for example, using the processing chamber 200 described herein.

The semiconductor device structure 400 includes film stacks 410 (such as gates, for example Si—SiGe gates) formed on a silicon substrate 401. The film stacks 410 include silicon-germanium (SiGe) layers 411 and silicon (Si) layers 412 disposed in an alternating arrangement, and a cap layer 415. A plurality of silicon nitride (SiN) spacers 413 are disposed on both sides of the respective SiGe layers 411. Using subject matter described herein, it is believed that the flatness, uniformity, and/or selectivity of the semiconductor device structure 400 can be enhanced. As an example, the flatness of recessed surfaces 403 between the film stacks 410 and/or the flatness of outer surfaces of the silicon nitride (SiN) spacers 413 and/or the Si layers 412 can be enhanced. As another example, the merging of the film stacks 410 can be controlled and/or prevented. As a further example, a source and drain material is formed with increased strain to facilitate enhanced device performance properties (such as contact resistance and/or mobility).

At FIG. 4A, a liner 421 is formed in the trenches between film stacks 410. The liner 421 can be formed on a bottom layer 407. The bottom layer 407 can be for example a bottom dielectric isolation (BDI) layer or part of the silicon substrate 401.

At FIG. 4B, sections of the liner 421 are crystallized, with sections remaining as amorphous liner material 523 on cap layers 415.

At FIG. 4C, the amorphous liner material 523 is etched to be removed from the cap layers 415.

At FIG. 4D, a source and drain material 525 is formed within the liner 521 to fill in the trench.

The liner 521 is formed on inner surfaces of a plurality of recesses of the semiconductor device structure 400, and the liner 521 lines a plurality of stacks (e.g., the film stacks 410) of the semiconductor device structure 400. The recesses are defined between the film stacks 410. In one or more embodiments, the liner 521 lines the Si layers 412 and the spacers 413. In one or more embodiments, the source and drain material 525 has a strain of 0.4 or higher. Other values and ranges are contemplated for the strain of the source and drain material 525. The formed crystalline liner 521 can have a thickness T1 that is less than 10 nm. In one or more embodiments, the thickness T1 is 5 nm or less.

FIGS. 5A-5B are schematic partial cross-sectional views of the method 300 conducted in relation to the semiconductor device structure 400, according to one or more embodiments.

At FIG. 5A, the source and drain material 525 is formed in trenches using operation 316 of the method 300. Sections of the source and drain material 525 can begin to merge toward each other. The source and drain material 525 can be deposited, for example, using nonselective deposition.

At FIG. 5B, the source and drain material 525 is etched using operation 320 of the method 300. Sections of the source and drain material 525 are removed to prevent merging, and further deposition can be conducted to facilitate bottom-up growth.

The present disclosure contemplates that the various gases described herein can flow into the processing chamber at various locations. For example, one of the deposition gas(es) (of operation 316) or the etch gase(s) (of operation 320 and/or operation 323) can flow laterally into the lower portion 236a through a sidewall of the processing chamber (e.g., through the one or more first gas inlets 214), and the other of the deposition gas(es) (of operation 316) or the etch gase(s) (of operation 320 and/or operation 323) can flow (e.g., vertically) into the lower portion 236a through the one or more holes 279 (such as holes, for example mesh holes) of the plate 274 (e.g., a showerhead). As another example, one of the etch composition (of operation 317) or the second etch composition (of operation 318) can flow laterally into the lower portion 236a through a sidewall of the processing chamber (e.g., through the one or more first gas inlets 214), and the other of the etch composition (of operation 317) or the second etch composition (of operation 318) can flow into the lower portion 236a through the one or more holes 279 (such as holes, for example mesh holes) of the isolation plate 274. The purge gas of operation 321 can flow along the same path as the etch gas(es).

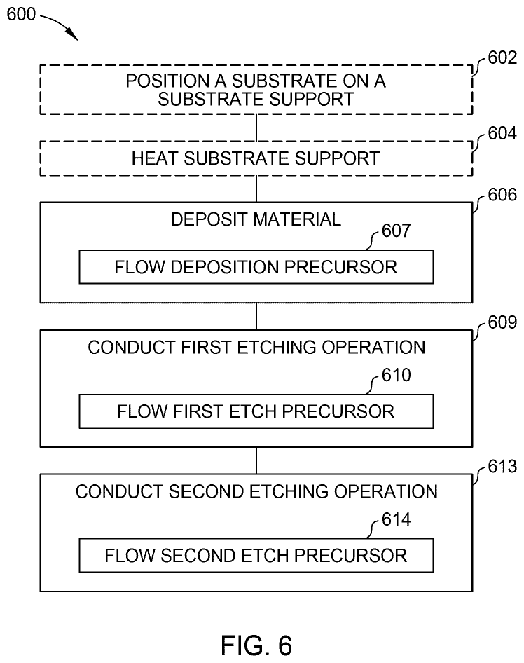

FIG. 6 is a schematic block diagram view of a method 600 of substrate processing, according to one or more embodiments.

Optional operation 602 includes positioning a substrate on a substrate support in a processing volume of a processing chamber. In one or more embodiments, the positioning includes moving a substrate support and/or a plurality of lift pins relative to each other to land the substrate on the substrate support.

Optional operation 604 of the method 600 includes heating the substrate support and/or the substrate in the processing volume to a target temperature.

Operation 606 includes depositing a material on a substrate. The depositing includes, at operation 607, flowing a deposition precursor for a deposition time and at a deposition flow rate. The depositing includes maintaining a deposition pressure. In one or more embodiments, the deposition pressure is less than 100 Torr, such as within a range of 35 Torr to 45 Torr, for example about 40 Torr. In one or more embodiments, the deposition precursor includes silicon and/or phosphorus, such as to form silicon phosphorus (SiP) film.

Operation 609 includes conducting a first etching operation on the material. The first etching operation includes, at operation 610, flowing a first etch precursor for a first etch time and at a first etch flow rate, and maintaining a first etch pressure. The first etch time is larger than the deposition time. In one or more embodiments, the first etch precursor includes hydrochloric acid (HCl). The first etch pressure is larger than the deposition pressure of operation 606. The first etch pressure is a first pressure ratio of the deposition pressure. In one or more embodiments, the first pressure ratio is at least 5.0. In one or more embodiments, the first pressure ratio is at least 10.0, for example within a range of 10.0 to 12.0, such as about 11.25. In one or more embodiments, the first etch pressure is 350 Torr or higher, such as within a range of 400 Torr to 500 Torr, for example about 450 Torr. In one or more embodiments, the depositing of operation 606 and the first etching operation of operation 609 are sequentially repeated for a first plurality of cycles. For example, operation 606 and operation 609 are sequentially repeated for the first plurality of cycles. As an example, one of the first cycles includes conducting operation 606 once and conducting operation 609 once.

Operation 613 includes conducting a second etching operation on the material. The second etching operation includes flowing a second etch precursor at operation 614 for a second etch time and at a second etch flow rate. The second etch time is larger than the first etch time. In one or more embodiments, the second etch precursor includes hydrochloric acid (HCl). The second etch flow rate is greater than the first etch flow rate of operation 609. The second etch flow rate is a flow ratio of the first etch flow rate. In one or more embodiments, the flow ratio is at least 1.30. In one or more embodiments, the flow ratio is within a range of 1.40 to 1.60, such as about 1.50.

The second etching operation includes maintaining a second etch pressure. The second etch pressure is greater than the deposition pressure. In one or more embodiments, the second etch pressure is less than the first etch pressure. In one or more embodiments, the second etch pressure is 100 Torr or less, such as within a range of 45 Torr to 55 Torr, such as about 50 Torr. The second etch pressure is a second pressure ratio of the deposition pressure. In one or more embodiments, the second pressure ratio is at least 1.1. In one or more embodiments, the second pressure ratio is within a range of 1.15 to 1.35, such as about 1.25. The second etch flow rate is greater than the first etch flow rate. The first etching operation and/or the second etching operation can etch away the deposited film (such as SiP film) such that remaining film is mostly or entirely crystalline film (such as crystalline SiP).

In one or more embodiments, the depositing of operation 606 and the second etching operation of operation 613 are sequentially repeated for a second plurality of cycles that is lesser than the first plurality of cycles. For example, after the first plurality of cycles (of operation 606 and operation 609) are completed, operation 606 and operation 613 are sequentially repeated for the second plurality of cycles. As an example, one of the second cycles includes conducting operation 606 once and conducting operation 613 once. In one or more embodiments, the second etching operation is continuously conducted for the second etch time (e.g., following the first plurality of cycles), and the second etch time is at least 200 seconds.

The deposition of operation 606, the first etching operation of operation 609, and/or the second etching operation of operation 613 respectively include maintaining a temperature. The temperature can be the same as the target temperature of operation 604. In one or more embodiments, the temperature respectively for operation 606, operation 609, and/or operation 613 maintain a temperature of less than 700 degrees Celsius, such as 400 degrees Celsius to 600 degrees Celsius, for example about 498 Celsius, or 500 degrees Celsius or less.

Process gases (e.g., the deposition precursor, the first etching precursor, and/or the second etching precursor) flow over the substrate 202 (FIG. 2) to process the substrate 202. The process gases can flow between the substrate support 206 and a plate apparatus (such as the plate apparatus 272) spaced from the substrate support 206. The present disclosure contemplates that the plate apparatus can be omitted from the processing chamber 200.

The present disclosure contemplates that the operations of the method 600 can be conducted in a variety of sequences. For example, the deposition of operation 606 can be conducted before or after the first etching operation of operation 609 and/or the second etching operation of operation 613. Moreover, one or more of the operations of the method 600 can be omitted for some or all of a plurality of cycles. For example, some cycles can include the deposition of operation 606, and some cycles can omit operation 606 and include the etching of operation 609 and/or operation 613.

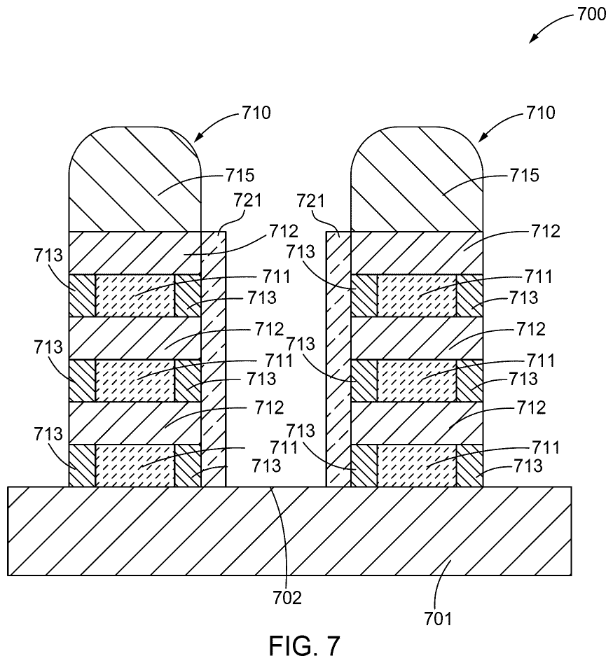

FIG. 7 is a schematic partial cross-sectional view of a semiconductor device structure 700, according to one or more embodiments. The semiconductor device structure 700 can be made, for example, using one or more of the processing chambers (such as the processing chamber 200) and/or one or more of the methods (such as the method 300, the method 600, and/or the method 1000) described herein.

The semiconductor device structure 700 includes fins 710 formed on a silicon substrate 701. The fins 710 include silicon-germanium (SiGe) layers 711 and silicon (Si) layers 712 disposed in an alternating arrangement, and a cap layer 715. A plurality of silicon nitride (SiN) spacers 713 are disposed on both sides of the respective SiGe layers 711. Using subject matter described herein, it is believed that the flatness, uniformity, and/or selectivity of the semiconductor device structure 700 can be enhanced. As an example, the flatness of recessed surfaces 702 between the fins 710 and/or the flatness of outer surfaces of the silicon nitride (SiN) spacers 713 and/or the Si layers 712 can be enhanced. As another example, the merging of the fins 710 can be controlled and/or prevented.

FIG. 7 shows silicon phosphorus (SiP) film 721 formed (e.g., progressively epitaxially grown and etched) in the trenches between the fins 710. Using for example the method 600 described herein, the SiP film 721 is formed (deposited and etched) in a manner that reduces or eliminates merging of the SiP film 721 and/or reduces or eliminates the formation of voids in the SiP film 721.

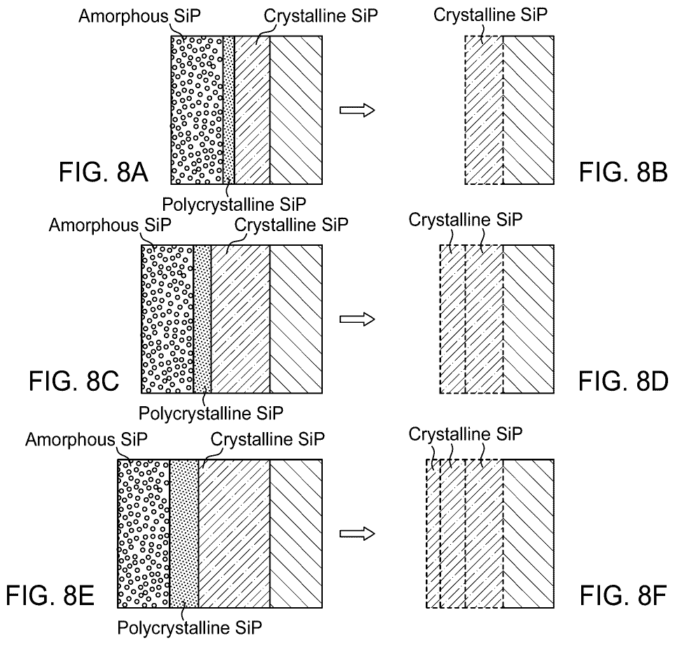

FIGS. 8A-8F are schematic side views of cyclic deposition-etch operations, according to one or more embodiments.

FIG. 8A and FIG. 8B show the first plurality of cycles of the method 600. FIG. 8A shows the results of operation 606 of the method in the first plurality of cycles. FIG. 8B shows the results of operation 609 of the method in the first plurality of cycles. In FIG. 8B, the etching has removed amorphous film (e.g., amorphous SiP) and polycrystalline film (e.g., polycrystalline SiP). In FIGS. 8A and 8B, the deposition-to-etch ratio can be greater than 1.0, such as about 1.5.

FIG. 8C and FIG. 8D show the second plurality of cycles of the method 600. FIG. 8C shows the results of operation 606 of the method in the second plurality of cycles. FIG. 8D shows the results of operation 613 of the method in the second plurality of cycles. In FIG. 8D, the etching has removed amorphous film (e.g., amorphous SiP) and polycrystalline film (e.g., polycrystalline SiP). In FIGS. 8C and 8D, the deposition-to-etch ratio is less than the deposition-to-etch ratio in FIGS. 8A and 8B. For example, the deposition-to-etch ratio in FIGS. 8C and 8D can be about 1.2 or less, such as 1.0 or less.

FIG. 8E and FIG. 8F show an optional third plurality of cycles of the method 600. FIG. 8E shows the results of operation 606 of the method in the third plurality of cycles. FIG. 8F shows the results of a third etching operation that can have a lower deposition-to-etch ratio than in FIGS. 8C and 8D. In FIG. 8F, the etching has removed amorphous film (e.g., amorphous SiP) and polycrystalline film (e.g., polycrystalline SiP). In FIGS. 8E and 8F, the deposition-to-etch ratio can be about 0.9 or less. In one or more embodiments, the deposition-to-etch ratio decreases across the plurality of first cycles, the plurality of second cycles, and/or the plurality of third cycles. In one or more embodiments, the second etch time of operation 613 is different than (such as larger than) the first etch time of operation 609. In one or more embodiments, the third etching operation involves a third etch flow rate larger than the second etch flow rate of the second etching operation, and/or a third etch time larger than the second etch time of the second etching operation. The present disclosure contemplates that one or more additional sets of cycles can be included in the method 600, which respectively includes the deposition of operation 606 and a respective etching operation that progressively increases etching (such as by using a higher etch flow rate and/or a higher etch time) relative to the third etching operation.

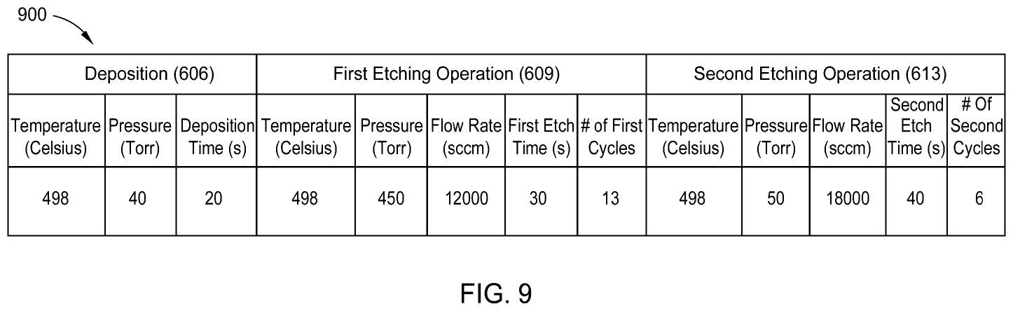

FIG. 9 is schematic table view of a table 900 of parameters that can be used in the method 600, according to one or more embodiments.

The parameters in the table 900 are exemplary. The present disclosure contemplates that other values can be used that deviate from the exemplary values in the table 900.

Benefits of the present disclosure include quick and efficient formation of materials (such as silicon-containing materials), such as in trenches, with reduced or eliminated (or controlled) merging of the materials, and with reduced or eliminated formation of voids in the deposited materials. Benefits also include reduced or eliminated notches of the deposited materials. The materials can be formed progressively (such as cyclically). Benefits also include enhanced device performance and reduced downtime.

It is contemplated that one or more aspects disclosed herein may be combined. As an example, one or more aspects, features, components, operations and/or properties of the processing chamber 200, the method 600, the semiconductor device structure 700, the cycles of FIGS. 8A-8F, and/or the parameters of FIG. 9 may be combined. Moreover, it is contemplated that one or more aspects disclosed herein may include some or all of the aforementioned benefits.

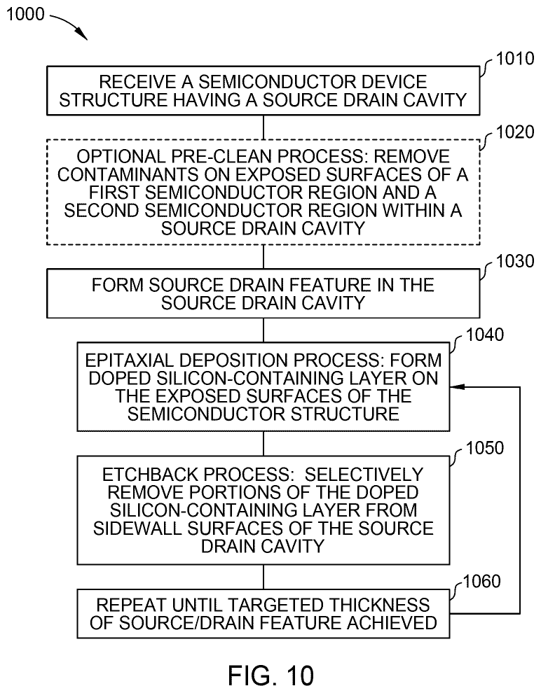

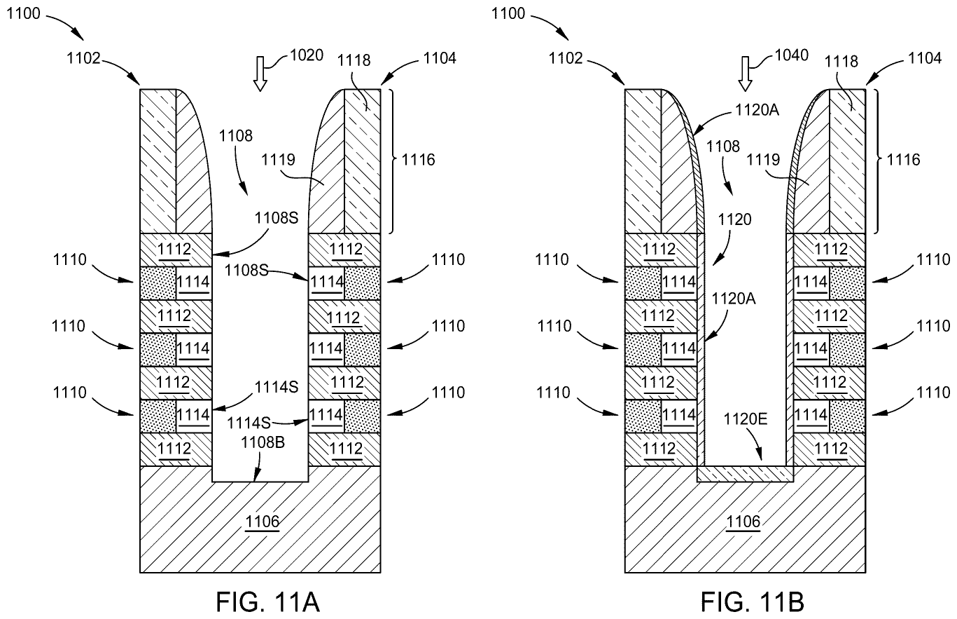

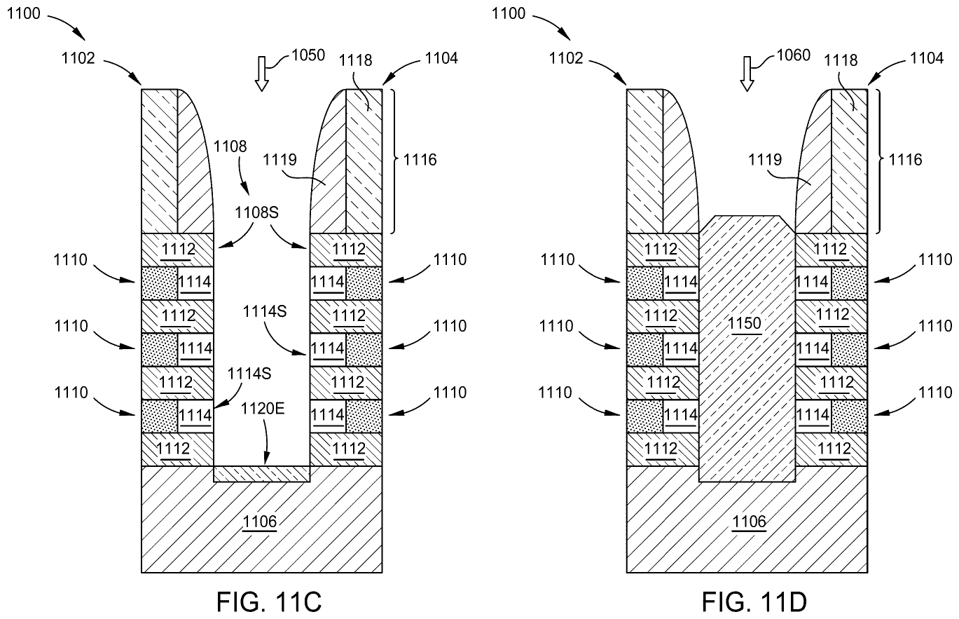

FIG. 10 illustrates an exemplary flow chart of a method 1000 in accordance with one or more implementations of the present disclosure. FIGS. 11A-11D illustrate schematic side views of various stages of manufacturing a semiconductor device structure 1100 according to the method 1000 of FIG. 10 in accordance with one or more implementations of the present disclosure. Although FIGS. 11A-11D are described in relation to the method 1000, it will be appreciated that the semiconductor device structures 1100 disclosed in FIGS. 11A-11D are not limited to the method 1000 but instead may stand alone as structures independent of the method 1000. Similarly, although the method 1000 is described in relation to FIGS. 11A-11D, it will be appreciated that the method 1000 is not limited to the semiconductor device structures 1100 disclosed in FIGS. 11A-11D but instead may stand alone independent of the semiconductor device structures 1100 disclosed in FIGS. 11A-11D. It should be understood that FIGS. 11A-11D illustrate only partial schematic views of the semiconductor device structure, and the semiconductor device structure 1100 may contain any number of additional layers and/or additional materials common to semiconductor device structures, which are not shown for the sake of brevity. It should also be noted that although the method 1000 illustrated in FIG. 10 is described sequentially, other process sequences that include one or more operations that have been omitted and/or added, and/or have been rearranged in another desirable order, fall within the scope of the implementations of the disclosure provided herein. The method 1000 may be performed using any suitable system, for example, the multi-chamber processing system 100.

Referring to FIG. 11A, at operation 1010 a semiconductor device structure 1100 having a trench 1108 in which a S/D region is formed is received. The semiconductor device structure 1100 may be or be part of a multi-gate device with three-dimensional architecture, such as fin-based semiconductor devices including nano-FETs and gate-all-around (GAA) transistor devices. The semiconductor device structure 1100 includes a first semiconductor region 1102 also referred to as a first fin structure and a second semiconductor region 1104 also referred to as a second fin structure formed on a substrate 1106. The first semiconductor region 1102 and the second semiconductor region 1104 are separated by a feature, such as the trench 1108 or a source/drain cavity, which exposes the substrate 1106. In one or more embodiments, a portion of the trench 1108 extends into the substrate 1106 as shown in FIG. 11A.

The term “substrate” as used herein refers to a layer of material that serves as a basis for subsequent processing operations and includes a surface to be cleaned. The substrate may be a silicon-based material or any suitable insulating materials or conductive materials as needed. The substrate may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

As shown in FIG. 11A, the first semiconductor region 1102 and the second semiconductor region 1104 each include first semiconductor layer(s) 1110 and second semiconductor layer(s) 1112 that are alternately and repeatedly stacked on the substrate 1106. Although the example shown in FIG. 11A shows three pairs, each pair including the first semiconductor layer 1110 and the second semiconductor layer 1112, the number of pairs may be varied based on different process needs with or without the first semiconductor layer(s) 1110 and the second semiconductor layer(s) 1112 being needed. The first semiconductor layer(s) 1110 are formed of a first material having etch selectivity to a second material of which the second semiconductor layer(s) 1112 are formed (i.e., an etch rate of the first material is higher than an etch rate of the second material). The etch selectivity (i.e., a ratio of the etch rate of the first material to the etch rate of the second material) is between about 10:1 to 200:1. Example combinations of the first material and the second material include silicon germanium (SiGe)/silicon (Si), silicon germanium (SiGe)/germanium (Ge), and germanium tin (GeSn)/silicon (Si). In one or more embodiments, the first semiconductor layer(s) 1110 are or include SiGe and the second semiconductor layer(s) 1112 are or include silicon, for example, crystalline silicon.

The first semiconductor layer(s) 1110 may be selectively etched to form indentations at the end of the first semiconductor layer(s) 1110 facing the trench 1108, in each of which an inner spacer 1114 is formed. The inner spacer 1114 may be formed of dielectric material, such as silicon nitride (Si₃N₄), silicon oxynitride (SiON), or silicon oxycarbide (SiOCN). Although the outer sidewalls 1114S of the inner spacer 1114 is illustrated as being flush with sidewalls of the second semiconductor layer(s) 1112, the outer sidewalls 1114S of the inner spacer 1114 may extend beyond or be recessed from sidewalls of the second semiconductor layer(s) 1112.

The second semiconductor layer(s) 1112 may serve as channels having a width of between several nanometers and several tens of nanometers. The first semiconductor layer(s) 1110 and the second semiconductor layer(s) 1112 can be nanostructures, for example, nanowires or nanosheets.

The first semiconductor layer(s) 1110 and the second semiconductor layer(s) 1112 may be formed using any suitable deposition technique, such as chemical vapor deposition (CVD), atomic layer deposition (ALD), or physical vapor deposition (PVD), and the trench 1108 is formed by a patterning technique, such as a lithography and etch process. The first semiconductor layer(s) 1110 and the second semiconductor layer(s) 1112 may each have thickness in a range from about 3 nm to about 15 nm, for example, about 10 nm. The selective etching of the first semiconductor layer(s) 1110 may be performed by any appropriate etch process, such as a dry plasma etch process.

In one or more embodiments, the semiconductor device structure 1100 further includes a dummy gate structure (also referred to as a “dielectric layer”) 1116 formed over at least a portion of each of the first semiconductor region 1102 and the second semiconductor region 1104. The dummy gate structure 1116 includes a dummy gate 1118. The dummy gate 1118 may be or include a conductive or nonconductive material and may be selected from amorphous silicon, doped or undoped polycrystalline silicon (polysilicon), polycrystalline silicon-germanium (poly-SiGe), silicon oxide, metallic nitrides, metallic silicides, metallic oxides, and metals. The dummy gate 1118 may be formed using any suitable techniques such as physical vapor deposition (PVD), plasma enhanced chemical vapor deposition (PECVD), CVD, ALD, or the like.

The dummy gate structure 1116 may further include one or more spacers 1119. The spacers 1119 may function as a spacer for forming self-aligned source/drain regions. The spacers 1119 may be formed along the sidewalls of the dummy gate 1118. The spacers 1119 may be formed of silicon oxycarbonitride, silicon oxide, silicon nitride, silicon oxynitride, or the like, using any suitable techniques such as thermal oxidation, or deposited by PECVD, CVD, ALD, or the like.

The trench 1108 is defined by a pair of opposing sidewall surfaces 1108S and a bottom surface 1108B. The sidewall surfaces 1108S may be defined by the dummy gate structure 1116 and the alternating pairs of the first semiconductor layer(s) 1110/inner spacers 1114 and the second semiconductor layer(s) 1112. In one or more embodiments, the bottom surface 1108B of the trench 1108 is defined by the substrate 1106. In one or more other embodiments, the bottom surface 1108B is defined by a dielectric material, for example, a bottom dielectric isolation (BDI) layer.

Referring to FIG. 11A, optionally at operation 1020, a pre-clean process is performed. The pre-clean process of operation 1020 may be performed in a processing chamber, such as the processing chamber 122 shown in FIG. 1 or the processing chamber 200 shown in FIG. 2. In some embodiments, the pre-clean process of operation 1020 and the deposition process of operation 1030 are performed in-situ in the same processing chamber, to minimize regrowth of oxide layers.

The pre-clean process is configured to remove contaminants, such as native oxide layers, or patterning residues (e.g., fluorocarbons) formed on the exposed surfaces of the first semiconductor region 1102 and the second semiconductor region 1104 within the trench 1108.

In one or more embodiments, the pre-clean etch process includes a wet etch process, using a cleaning solution, such as a hydrofluoric acid (HF)-last type cleaning solution, ozonated water cleaning solution, HF and hydrogen peroxide (H₂O₂) solution, and/or other suitable cleaning solution. The cleaning solution may be heated.

In one or more embodiments, the pre-clean process includes an isotropic plasma etching process, such as a SiCoNi™ dry chemical etching process, using a plasma formed from a gas including ammonia (NH₃), nitrogen trifluoride (NF₃), hydrogen fluoride (HF), or a combination thereof, and a carrier gas, such as nitrogen (N₂), hydrogen (H₂), or a combination thereof. The dry chemical etching process is selective for oxide layers, and thus does not readily etch silicon, germanium, or nitride layers regardless of whether the layers are amorphous, crystalline or polycrystalline. Selectivity of the dry chemical etching process for oxide versus silicon or germanium is at least about 3:1, and usually 5:1 or better, sometimes 10:1. The dry chemical etching process is also highly selective of oxide versus nitride. The selectivity of the dry chemical etching process versus nitride is at least about 3:1, usually 5:1 or better, sometimes 10:1.

In one or more embodiments, the pre-clean process includes a thermal etching process. The one or more process gases etch the surface of the substrate to remove oxide impurities. The one or more process gases include hydrogen fluoride (HF), ammonia (NH₃), water, or an alcohol. In one or more embodiments, the pre-clean process is a thermal process.

In one or more embodiments, the pre-clean process includes an anisotropic remote plasma assisted dry etch process, such as a reactive ion etching (RIE) process, using a plasma formed from a gas including argon (Ar), helium (He), or a combination thereof. The plasma effluents directionally bombard and remove contaminants on the exposed surfaces of the first semiconductor region 1102 and the second semiconductor region 1104 within the trench 1108.

In one or more embodiments, the pre-clean process may include an inductively coupled plasma (ICP) etching process, using a plasma formed from a gas including chlorine (Cl₂) and hydrogen (H₂), and a carrier gas including argon (Ar) and helium (He).

In one or more embodiments, the pre-clean process includes exposing the semiconductor device structure 1100 to atomic hydrogen radicals.

In one or more embodiments, the pre-clean process further includes exposing the semiconductor device structure 1100 to a thermal annealing process at a temperature of 600 degrees Celsius or higher, for example, in a range from about 650 degrees Celsius to about 900 degrees Celsius. The cleaning process can remove surface oxide, carbon, and debris to ensure a clean semiconductor surface, which facilitates growth of high-quality epitaxial layers.

Referring to FIGS. 11A-11D, at operation 1030, a source/drain feature 1150 is formed in the trench 1108 or the source/drain cavity. The source/drain feature 1150 fills or partially fills the trench 1108 to a targeted thickness in between the first semiconductor region 1102 and the second semiconductor region 1104. The composition of the source/drain feature 1150 depends on the conductivity type of the semiconductor device structure 1100. If the semiconductor device structure 1100 is an n-type structure, the source/drain feature 1150 may include silicon (Si) doped with an n-type dopant such as phosphorous (P), antimony (Sb), or arsenic (As). If the semiconductor device structure 1100 is a p-type structure, the source/drain feature 1150 may include silicon (Si) or SiGe doped with a p-type dopant such as boron (B) or gallium (Ga). In some embodiments, as is shown in FIG. 11B, FIG. 11C, and FIG. 11D the source/drain feature 1150 includes multiple epitaxial layers each formed by an epitaxial process. The source/drain feature 1150 may be epitaxially and selectively formed from the exposed sidewall surfaces 1108S of the second semiconductor layer(s) 1112, the inner spacers 1114 and the bottom surface 1108B. Suitable epitaxial processes include vapor-phase epitaxial (VPE), ultra-high vacuum CVD (UHV-CVD), molecular beam epitaxy (MBE), low pressure CVD (LPCVD), plasma epitaxy, and/or other suitable processes. The epitaxial growth process uses gaseous precursors, which interact with the material of the substrate 1106 and the materials of the first semiconductor layer(s) 1110 and the second semiconductor layer(s) 1112.

The source/drain feature 1150 is epitaxially grown by a cyclic deposition/etchback process including an epitaxial deposition process performed during operation 1040 followed by an etchback process performed during operation 1050. At operation 1060, the epitaxial deposition process and the etchback process are repeated for a number of cycles until the source/drain feature 1150 achieves a targeted thickness.

At operation 1040, an epitaxial deposition process is performed to form the source/drain feature 1150 shown in FIG. 11D. The source/drain feature 1150 fills the trench 1108 in between the first semiconductor region 1102 and the second semiconductor region 1104. The composition of the source/drain feature 1150 depends on the conductivity type of the semiconductor device structure 1100. If the semiconductor device structure 1100 is an n-type structure, the source/drain feature 1150 includes silicon (Si) doped with an n-type dopant such as phosphorous (P), antimony (Sb), or arsenic (As). If the semiconductor device structure 1100 is a p-type structure, the source/drain feature 1150 includes silicon (Si) doped with a p-type dopant such as boron (b) or gallium (Ga). In some embodiments, as is shown in FIG. 11B, FIG. 11C, and FIG. 11D the source/drain feature 1150 includes multiple epitaxial layers each formed by an epitaxial process. The source/drain feature 1150 may be epitaxially and selectively formed from the exposed sidewall surfaces 1108S of the second semiconductor layer(s) 1112, the inner spacers 1114 and the bottom surface 1108B, which is defined by the substrate 1106. Suitable epitaxial processes include vapor-phase epitaxial (VPE), ultra-high vacuum CVD (UHV-CVD), molecular beam epitaxy (MBE), low pressure CVD (LPCVD), plasma epitaxy, and/or other suitable processes. The epitaxial growth process uses gaseous precursors, which interact with the material of the substrate 1106 and the materials of the first semiconductor layer(s) 1110 and the second semiconductor layer(s) 1112.

The source/drain feature 1150 is epitaxially grown by a cyclic deposition/etch process including an epitaxial deposition process performed during operation 1040 followed by an etch process performed during operation 1050. The deposition process and the etch process are repeated for a number of cycles until the source/drain feature 1150 achieves a targeted thickness.

Referring to FIG. 11B, at operation 1040 an epitaxial deposition process is performed to deposit a doped silicon-containing layer 1120 on the exposed surfaces of the semiconductor device structure 1100 within the trench 1108 (i.e., the sidewall surfaces 1112S defined by the second semiconductor layer 1112 and the inner spacer 1114, and the bottom surface 1108B). The deposition process of operation 1040 can be performed in a processing chamber, such as the processing chamber 126, 128, or 130 shown in FIG. 1, or the processing chamber 200 shown in FIG. 2.

The doped silicon-containing layer 1120 includes both doped amorphous silicon portions 1120A and doped epitaxial silicon portions 1120E. Since the trench 1108 is defined by both monocrystalline surfaces and non-monocrystalline surfaces, the doped amorphous silicon portions 1120A form over the non-monocrystalline surfaces and the doped epitaxial silicon portions 1120E form over the monocrystalline surfaces. Monocrystalline surfaces include the bare crystalline substrate, for example, the bottom surface 1108B or a deposited single crystal layer usually made from a material such as silicon, germanium, silicon germanium or silicon carbon. Non-monocrystalline surfaces include dielectric materials, for example, the inner spacers 1114, such as oxides or nitrides, specifically silicon oxide or silicon nitride, as well as amorphous silicon surfaces. Accordingly, the doped epitaxial silicon portions 1120E form over the bottom surface 1108B (if the BDI is not present) and the doped amorphous silicon portions 1120A form over the inner spacers 1114. If the BDI is present, the doped amorphous silicon portions 1120A also form over the bottom surface 1108B. The doped amorphous silicon portions 1120A can be challenging to remove and lead to defects in the source/drain feature 1150.

The doped silicon-containing layer 1120 may be doped with n-type dopants such as phosphorus (P), antimony (Sb), or Arsenic (As), with a concentration between about 10¹⁹ cm⁻³ and 5×10²¹ cm⁻³, depending upon the targeted conductive characteristic of the source/drain feature 1150 to be formed in the trench 1108.

In one or more embodiments, the doped silicon-containing layer 1120 is epitaxially grown using a silicon-containing precursor gas and a phosphorous-containing precursor gas. The silicon-containing precursor gas can be or include silane (SiH₄), a higher order silane, a halogenated silane, an organosilane, or a combination thereof. Higher order silanes include compounds with an empirical formula SiₓH₍₂ₓ₊₂₎, such as disilane (Si₂H₆), trisilane (Si₃H₈), and tetrasilane (Si₄H₁₀). Halogenated silanes include compounds with the empirical formula X′_{y}SiₓH_{(2x+2-y}), where X′=F, Cl, Br or I, such as dichlorosilane (SiH₂Cl₂), tetrachlorosilane (SiCl₄), and hexachlorodisilane (Si₂Cl₆), and trichlorosilane (SiHCl₃). Organosilanes include compounds with an empirical formula R_{y}SiₓH_{(2x+2-y)}, where R=methyl, ethyl, propyl or butyl, such as methylsilane ((CH₃)SiH₃), dimethylsilane ((CH₃)₂SiH₂), ethylsilane ((CH₃CH₂)SiH₃), methyldisilane ((CH₃)Si₂H₅), dimethyldisilane ((CH₃)₂Si₂H₄) and hexamethyldisilane ((CH₃)₆Si₂).

In one or more embodiments, the phosphorous dopant source gas includes one or a combination of phosphine source gas, phosphorous halide source gases, and organic phosphorous source gases, for example, alkylphosphines. Phosphorous halide source gases may include compounds with the formula PH(3−n)X′n where H is hydrogen, X′ is a halogen such as CI, F, Br, or I, and n=1, 2, or 3. Suitable examples of phosphorous halide source gases include PCl3. Organic phosphorous source gases may include organophosphine compounds with the formula RnPH(3−n), where R is methyl, ethyl, propyl, or butyl, and x=1, 2, or 3. Suitable organophosphines include trimethylphosphine ((CH₃)₃P), dimethylphosphine ((CH₃)₂PH), triethylphosphine ((CH₃CH₂)₃P), tert-butylphosphine (C4H11P), and diethylphosphine ((CH₃CH₂)₂PH). In one or more embodiments, the phosphorous dopant source gas includes an organophosphine source gas. In at least one particular implementation, tert-butylphosphine is used.

In one or more embodiments, the silicon-containing precursor gas is disilane and the phosphorous dopant source gas is tert-butylphosphine. Organophosphine dopant source gases have been found to increase the levels of phosphorous dopant in the doped silicon-containing layer 1120 in comparison with phosphine gas. In addition, organophosphine dopant source gases have been found to suppress nucleation on dielectric surfaces which reduces the formation of undesirable amorphous silicon on dielectric surfaces such as the inner spacers 1114. Further, organophosphine dopant source gases enable deposition at lower temperatures in comparison with phosphine dopant source gases. Not to be bound by theory, but it is believed that hydrogen scavenging performed by the leaving groups of the organophosphine dopant source gas reduces the barrier for low temperature growth.

A flow rate of the silicon-containing precursor gas can be in a range from about 10 standard cubic centimeters per minute (sccm) to about 1000 sccm and a flow rate of the phosphorous dopant source gas can be in a range from about 5 sccm to about 30 sccm. A first pressure of an environment in a processing chamber in which the epitaxial growth is performed can be maintained in a range from about 3 Torr to about to about 200 Torr, or from about 5 Torr to about 100 Torr, or from about 5 Torr to about 50 Torr, or from about 30 Torr to about 50 Torr. A first temperature of the substrate 406 during the epitaxial growth can be maintained at about 550° C. or less, or at about 500° C. or less, or at about 450° C. or less, or at about 400° C. or less, and more particularly in a range from about 200° C. to about 500° C., or from about 300° C. to about 450° C., or from about 350° C. to about 400° C., or from about 400° C. to about 450° C.

The phosphorous-containing source gas may be provided along with a carrier gas. The carrier gas may have a flow rate in a range from about 1 SLM to about 100 SLM, or in a range from about 2 SLM to about 30 SLM, or in a range from about 2 SLM to about 5 SLM. Suitable carrier gases include nitrogen (N2), hydrogen (H2), argon, helium, or combinations thereof. The carrier gas may be selected based on the reactants used and/or the process temperature during the soak process.

Referring to FIG. 11C, at operation 1050 a selective etchback process is performed. The selective etchback process is performed to remove the doped amorphous silicon portions 1120A of the doped silicon-containing layer 1120. The selective etchback process may include any appropriate etch process that selectively removes amorphous silicon relative to epitaxial silicon. In one or more embodiments, the selective etchback process is performed in-situ in the same chamber as the epitaxial deposition process in operation 1040, such as the processing chamber 200 shown in FIG. 2. In other embodiments, the selective etchback process is performed ex-situ in a different processing chamber, such as the processing chamber 122 shown in FIG. 1, from the processing chamber in which the epitaxial deposition process of operation 1040 is performed.

In the selective etchback process of operation 1050, the doped amorphous silicon portions 1120A formed over the dummy gate structure 1116 (e.g., silicon dioxide (SiO₂)) and any portions of the doped amorphous silicon portions 1120A that are along the sidewall surfaces 1108S are removed, by an appropriate etching gas. The doped amorphous silicon portions 1120A formed over the dummy gate structure 1116 and along the sidewall surfaces 1108S can be etched at a faster rate than the doped epitaxial silicon portion 1120E along the bottom surface 1108B of the trench 1108 and thus can be etched selectively relative to the doped epitaxial silicon portion 1120E along the bottom the trench 1108. The selective etchback process in operation 1050 may also remove polycrystalline or defective material, if any.

The selective etch process of operation 1050 includes flowing an etchant process gas into a processing region to expose the semiconductor device structure 1100 to the etchant process gas. The etchant process gas can be or include HCl, HF, HBr, Br₂, Si₂Cl₆, SiCl₄, SiHCI₃, SiH₂Cl₂, CCI₄, Cl₂, GeCl₄, GeHCl₃, or a combination thereof. A flow rate of an etchant gas can be in a range from about 0 sccm to about 100 sccm. A carrier gas, for example, an inert gas, such as nitrogen (N₂), argon (Ar), the like, or a combination thereof, can be used in combination with the etchant process gas. In one or more embodiments, the etchant process gas includes GeH4 and HCl.

A flow rate of the etchant process gas can be in a range from about 10 standard cubic centimeters per minute (sccm) to about 1000 sccm. A second pressure of an environment in a processing chamber in which the selective etchback process is performed can be maintained in a range from about 200 Torr to about 500 Torr, or from about 200 Torr to about 400 Torr, or from about 250 Torr to about 350 Torr, or from about 250 Torr to about 300 Torr. A second temperature of the substrate 406 during the selective etchback process can be maintained at about 200° C. or greater, or at about 300° C. or greater, or at about 450° C. or greater, or at about 500° C. or greater, and more particularly in a range from about 200° C. to about 600° C., or from about 300° C. to about 600° C., or from about 400° C. to about 600° C., or from about 450° C. to about 550° C., or from about 400° C. to about 500° C. In one or more embodiments the second pressure is in a range from about 250 Torr to about 350 Torr and the second temperature is in a range from about 450° C. to about 550° C.

In one or more embodiments, the epitaxial deposition process of operation 1040 is performed at a first temperature and a first pressure and the selective etchback process of operation 1050 is performed at a second temperature and a second pressure, the second temperature and the second pressure is greater than the first temperature and the first pressure. In one or more embodiments, the first temperature is 450 degrees Celsius or less and the first pressure is 40 Torr or less.

At operation 1060, the epitaxial deposition process of operation 1040 and the selective etchback process of operation 1050 may be repeated in a cyclic etch/dep process until the source/drain feature 1150 achieves a targeted thickness within the trench 1108 as shown in FIG. 11D. In one or more embodiments, the number of cycles is in a range from six cycles to fifteen cycles.

The previously described embodiments of the present disclosure have many advantages. Improved Quality and Performance: The cyclic epitaxial deposition and selective etchback process enhances the quality and performance of multi-gate devices like gate-all-around (GAA) transistors by reducing defects and improving uniformity. Precise Thickness Control: The cyclic process allows for precise thickness control of the n-type doped semiconductor layer, which helps achieve the targeted electrical properties. Reduced Defects: The selective etchback process removes unwanted amorphous portions of the semiconductor layer, which helps in reducing defects and improving the overall performance of the semiconductor device. Low-Temperature Deposition: The use of organophosphine dopant source gases enables deposition at lower temperatures compared to traditional phosphine dopant source gases. This is believed to be due to hydrogen scavenging performed by the leaving groups of the organophosphine dopant source gases, which reduces the barrier for low-temperature growth. Suppression of Undesirable Amorphous Silicon: Organophosphine dopant source gases have been found to suppress nucleation on dielectric surfaces, reducing the formation of undesirable amorphous silicon on these surfaces. However, the present disclosure does not necessitate that all the advantageous features and the advantages need to be incorporated into every embodiment of the present disclosure.

In the Summary and in the Detailed Description, and the Claims, and in the accompanying drawings, reference is made to particular features (including method operations) of the present disclosure. It is to be understood that the disclosure in this specification includes all possible combinations of such particular features. For example, where a particular feature is disclosed in the context of a particular aspect, implementation, implementation, or example of the present disclosure, or a particular claim, that feature can also be used, to the extent possible in combination with and/or in the context of other particular aspects and implementations of the present disclosure, and in the present disclosure generally.

Implementations and all the functional operations described in this specification can be implemented in digital electronic circuitry, or in computer software, firmware, or hardware, including the structural means disclosed in this specification and structural equivalents thereof, or in combinations of them. Implementations described herein can be implemented as one or more non-transitory computer program products, i.e., one or more computer programs tangibly embodied in a machine-readable storage device, for execution by, or to control the operation of, data processing apparatus, e.g., a programmable processor, a computer, or multiple processors or computers.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. Processors suitable for the execution of a computer program include, by way of example, both general and special purpose microprocessors, and any one or more processors of any kind of digital computer.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

The term “comprises,” and grammatical equivalents thereof are used herein to mean that other components, ingredients, operations, etcetera are optionally present. For example, an article “comprising” (or “which comprises”) components A, B, and C can consist of (i.e., contain only) components A, B, and C, or can contain not only components A, B, and C but also one or more other components. In addition, whenever a composition, an element or a group of elements is preceded with the transitional phrase “comprising” or grammatical equivalents thereof, it is understood that it is contemplated that the same composition or group of elements may be preceded with transitional phrases “consisting essentially of,” “consisting of,” “selected from the group of consisting of,” or “is” preceding the recitation of the composition, element, or elements and vice versa.

The disclosure contemplates that terms such as “couples,” “coupling,” “couple,” and “coupled” may include but are not limited to embedding, bonding, welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

Where reference is made herein to a method comprising two or more defined operations, the defined operations can be carried out in any order or simultaneously (except where the context excludes that possibility), and the method can include one or more other operations which are carried out before any of the defined operations, between two of the defined operations, or after all of the defined operations (except where the context excludes that possibility).

When introducing elements of the present disclosure or exemplary aspects or implementation(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to implementations of the present disclosure, other and further implementations of the disclosure may be devised without departing from the basic scope thereof, and the scope thereof is determined by the claims that follow.

1. A method of substrate processing, comprising:
forming a source and drain material on a structure of a substrate;
etching the source and drain material, the etching conducted in a plurality of etch cycles that respectively comprise:
flowing a purge gas, and
flowing an etch gas to etch the source and drain material.

2. The method of claim 1, wherein the etch gas is flowed for an etch time and the purge gas is flowed for a purge time that is greater than the etch time.

3. The method of claim 2, wherein the etch time is 5.0 seconds or less, and the purge time is 5.0 seconds or less.

4. The method of claim 1, further comprising forming a liner on the structure, wherein the source and drain material is formed on the liner, the structure comprises a plurality of stacks of the structure, the plurality of stacks respectively comprising a plurality of Si layers and a plurality of SiGe layers, and the liner lines the plurality of Si layers and spacers disposed outwardly of the plurality of SiGe layers.

5. The method of claim 1, wherein the etch gas includes one or more of: hydrochloric acid (HCl), chlorine gas (Cl₂), hydrogen bromide (HBr), phosphorus trichloride (PCl₃), arsenic trichloride (AsCl₃), or germanium trichloride (GeCl₄).

6. The method of claim 5, further comprising forming a liner on the structure using a formation temperature of 500 degrees Celsius or less, wherein the etch gas includes HCl and Cl₂ co-flowed in a carrier gas to enhance selectivity of the liner.

7. The method of claim 1, further comprising:
forming a liner on the structure using a formation temperature of 500 degrees Celsius or less; and
a second etching of the source and drain material after the plurality of etch cycles, the second etching comprising flowing a second etch gas, wherein the etch gas includes HCl and the second etch gas includes Cl₂.

8. The method of claim 7, wherein the forming and the etching are sequentially repeated for a plurality of cycles of a first dep-etch sequence, and then the forming and the second etching are sequentially repeated for a plurality of second cycles of a second dep-etch sequence.

9. The method of claim 1, wherein the forming of the source and drain material is conducted in a plurality of deposition cycles that respectively comprise:
a first deposition operation comprising simultaneously flowing a deposition gas and an etch composition at a first etch flow rate; and
a second deposition operation comprising simultaneously flowing the deposition gas and the etch composition at a second etch flow rate, wherein the second etch flow rate is larger than the first etch flow rate.

10. The method of claim 9, wherein the deposition gas comprises flowing a phosphorous dopant source gas comprising an organophosphine having the formula PRₙH₃₋ₙ, n is from 1 to 3, and R is an ethyl group, a propyl group, or a butyl group.

11. A method of substrate processing, comprising:
forming source and drain material on a structure of a substrate, the forming of the source and drain material is conducted in a plurality of deposition cycles that respectively comprise:
a first deposition operation comprising simultaneously flowing a deposition gas and an etch composition at a first etch flow rate, and
a second deposition operation comprising simultaneously flowing the deposition gas and the etch composition at a second etch flow rate, wherein the second etch flow rate is larger than the first etch flow rate.

12. The method of claim 11, wherein the deposition gas flows at a deposition flow rate, the first etch flow rate and the second etch flow rate respectively are a ratio of the deposition flow rate, and the ratio is less than 0.20.

13. The method of claim 12, wherein the deposition gas flows at a deposition flow rate, the first etch flow rate and the second etch flow rate respectively are a ratio of the deposition flow rate, and the ratio is 0.20 or higher.

14. The method of claim 11, wherein the second etch flow rate is a ratio of the first etch flow rate, and the ratio is greater than 1.0 and equal to or lesser than 1.4.

15. The method of claim 11, wherein the first etch flow rate is defined by a first etch-deposition ratio, and the second etch flow rate is defined by a second etch-deposition ratio that is greater than the first etch-deposition ratio.

16. The method of claim 11, wherein the first deposition operation has a first deposition time, and the second deposition operation has a second deposition time that is shorter than the first deposition time.

17. A non-transitory computer readable medium comprising instructions that, when executed, cause a plurality of operations to be conducted, the plurality of operations comprising:
forming a source and drain material on a structure of a substrate;
etching the source and drain material, the etching conducted in a plurality of etch cycles that respectively comprise:
flowing a purge gas, and
flowing an etch gas to etch the source and drain material.

18. The non-transitory computer readable medium of claim 17, wherein the etch gas is flowed for an etch time and the purge gas is flowed for a purge time that is greater than the etch time.

19. The non-transitory computer readable medium of claim 17, wherein the forming of the source and drain material is conducted in a plurality of deposition cycles that respectively comprise:
a first deposition operation comprising simultaneously flowing a deposition gas and an etch composition at a first etch flow rate; and
a second deposition operation comprising simultaneously flowing the deposition gas and the etch composition at a second etch flow rate, wherein the second etch flow rate is larger than the first etch flow rate.

20. The non-transitory computer readable medium of claim 19, wherein:
the first deposition operation has a first deposition time;
the second deposition operation has a second deposition time that is shorter than the first deposition time;
the first etch flow rate is defined by a first etch-deposition ratio; and
the second etch flow rate is defined by a second etch-deposition ratio that is greater than the first etch-deposition ratio.
